(19) United States
(12) Patent Application Publication
(10) Pub. No.: US 2025/0362610 A1
(43) Pub. Date: Nov. 27, 2025

(54) RESIST UNDERLAYER FILM-FORMING COMPOSITION

(71) Applicant: NISSAN CHEMICAL CORPORATION, Tokyo (JP)

(72) Inventors: Masahisa ENDO, Toyama (JP); Hayato HATTORI, Toyama (JP)

(73) Assignee: NISSAN CHEMICAL CORPORATION, Tokyo (JP)

(21) Appl. No.: 18/994,729

(22) PCT Filed: Jul. 12, 2023
(86) PCT No.: PCT/JP2023/025655

§ 371 Date: Jan. 15, 2025

(30) Foreign Application Priority Data
Jul. 19, 2022 (JP) 2022-114556

(51) Int. Cl. G03F 7/11; G03F 7/16; H01L 21/027; H01L 21/033; H01L 21/308

(52) U.S. Cl. CPC G03F 7/11; G03F 7/168; H01L 21/0276; H01L 21/0337; H01L 21/3081; H01L 21/3086

(57) ABSTRACT

A composition for forming a resist underlayer film contains a compound P that has a partial structure having a phenolic hydroxyl group on a benzene ring and at least one hydroxymethyl or methoxymethyl group at ortho-position of the phenolic hydroxyl group, in which the content of the compound P is 80% by mass or more relative to the total solid content in the composition.

### TECHNICAL FIELD

The present invention relates to a resist underlayer film-forming composition, a resist underlayer film which is a baked product of a coating film of the composition, a method for producing a semiconductor device using the composition.

### BACKGROUND ART

In production of semiconductor devices, fine processing is performed by a lithography process. The lithography process is known to have a problem that in exposure of a resist layer on a substrate to an ultraviolet laser such as a KrF excimer laser or an ArF excimer laser, a standing wave is generated by reflection of the ultraviolet laser by a surface of the substrate, and due to the influence of the standing wave, a resist pattern having a desired shape is not formed. For solving the problem, a resist underlayer film (antireflection film) has been provided between a substrate and a resist layer. It is known that a novolak resin is used as a composition for forming a resist underlayer film.

In addition, a lithography process is also known in which for reduction of the thickness of a resist layer, which is required in association with refinement of resist patterns, at least two resist underlayer films are formed, and the resist underlayer films are used as a mask material. Examples of the material for forming the at least two layers include organic resins (for example, acrylic resins and novolak resins), silicon resins (for example, organopolysiloxanes), and inorganic silicon compounds (for example, SiON and SiO₂). When dry etching is performed using a pattern formed from the organic resin layer as a mask, it is necessary that the pattern have etching resistance against an etching gas (for example, fluorocarbon).

As a composition for forming such a resist underlayer film, for example, Patent Literature 1 discloses a resist underlayer film-forming composition obtained by adding to a novolak resin a compound having a phenolic hydroxy group and a hydroxymethyl group on a benzene ring as a cross-linking agent.

### CITATION LIST

### Patent Literature

Patent Literature 1: WO 2014/208542

### SUMMARY OF INVENTION

### Technical Problem

However, the conventional resist underlayer film-forming compositions have not satisfactorily met the requirements of reduction of the amount of sublimates that would contaminate an apparatus, and enhancement of etching resistance in processing of a substrate, hardness in particular.

### Solution to Problem

The present invention solves the above problems. That is, the present invention includes the following.

[1]

A resist underlayer film-forming composition comprising a compound P having a partial structure comprising a benzene ring carrying thereon a phenolic hydroxy group and at least one hydroxymethyl or methoxymethyl group in an ortho position relative to the phenolic hydroxy group,
wherein the resist underlayer film-forming composition contains the compound P in a content of 80% by mass or more based on a total solid content in the composition.
   [2]

The resist underlayer film-forming composition according to [1], wherein the compound P is a compound represented by the following Formula (1):

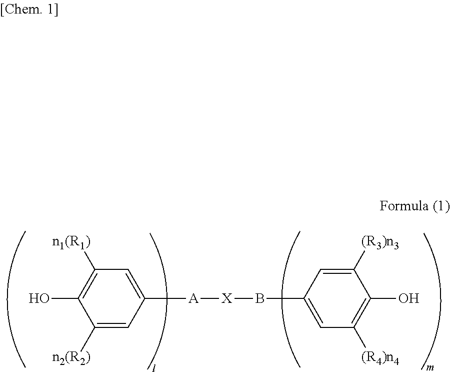

wherein R¹, R², R³ and R⁴ each independently represent a hydrogen atom, a hydroxymethyl group, or a methoxymethyl group,
A and B each independently represent an alkylene group having 1 or 2 carbon atoms and optionally substituted with a benzene ring or an alkyl group having 1 to 10 carbon atoms, or a single bond,
X represents an alkylene group having 1 or 2 carbon atoms and optionally substituted with a benzene ring or an alkyl group having 1 to 10 carbon atoms, an arylene group, or a single bond,
l and m each independently represent 1 or 2,
n1 to n4 are each independently 0 or 1, and satisfy

$$( ( n 1 + n 2 ) l + ( n 3 + n 4 ) m ) / ( 2 l + 2 m ) \geq 0.3 ,$$

with the proviso that not all of A, B and X is a single bond.
   [3]

The resist underlayer film-forming composition according to [1] or [2], wherein the resist underlayer film-forming composition contains the compound P in a content of 90% by weight or more based on a total solid content in the composition.

[4]

The resist underlayer film-forming composition according to any one of [1] to [3], wherein in Formula (1), each of R¹, R², R³ and R⁴ is a hydroxymethyl group.

[5]

The resist underlayer film-forming composition according to any one of [1] to [4], further comprising an acid and/or an acid generator.

[6]

The resist underlayer film-forming composition according to any one of [1] to [5], further comprising a surfactant.

[7]

The resist underlayer film-forming composition according to any one of [1] to [6], wherein the solvent includes a solvent having a boiling point of 160° C. or higher.

[8]

A resist underlayer film which is a baked product of a coating film of the composition according to any one of [1] to [7].

[9]

A method for producing a semiconductor device, comprising:
forming a resist underlayer film on a semiconductor substrate using the composition according to any one of [1] to [7];
forming a resist film on the formed resist underlayer film;
forming a resist pattern by irradiating the formed resist film with a light or electron beam and developing the irradiated film;
etching the resist underlayer film via the formed resist pattern to make a patterned resist underlayer film; and
processing the semiconductor substrate via the patterned resist underlayer film.
   [10]

A method for producing a semiconductor device, comprising:
forming a resist underlayer film on a semiconductor substrate using the composition according to any one of [1] to [7];
forming a hard mask on the formed resist underlayer film;
forming a resist film on the formed hard mask;
forming a resist pattern by irradiating the formed resist film with a light or electron beam and developing the irradiated film;
etching the hard mask via the formed resist pattern to make a patterned hard mask;
etching the resist underlayer film via the patterned hard mask to make a patterned resist underlayer film; and
processing the semiconductor substrate via the patterned resist underlayer film.

### Advantageous Effects of Invention

According to the present invention, there is provided a novel resist underlayer film-forming composition which meets the requirements of reduction of the amount of sublimates that would contaminate an apparatus, and enhancement of etching resistance in processing of a substrate, hardness in particular, while maintaining the other desirable properties.

### DESCRIPTION OF EMBODIMENTS

### [Resist Underlayer Film-Forming Composition]

A resist underlayer film-forming composition according to the present invention contains a compound P having a partial structure comprising a benzene ring carrying thereon a phenolic hydroxy group and at least one hydroxymethyl or methoxymethyl group in an ortho position relative to the phenolic hydroxy group, in an amount of 80% by mass or more based on a total solid content in the composition, and a solvent. The term “solid content” refers to components other than the solvent(s) in the composition.

From the viewpoint of obtaining a resist underlayer film having high hardness, the compound P is contained in an amount of preferably 90% by mass or more, more preferably 95% by mass or more, and most preferably 100% by mass based on a total solid content in the composition.

### [Compound P]

The compound P has a partial structure comprising a benzene ring carrying thereon a phenolic hydroxy group and at least one hydroxymethyl or methoxymethyl group in an ortho position relative to the phenolic hydroxy group.

More specifically, the compound P is a compound represented by the following Formula (1):

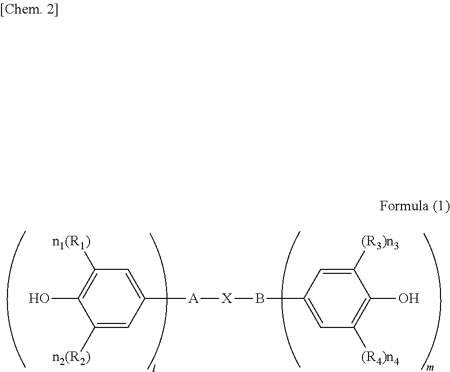

wherein R¹, R², R³ and R⁴ each independently represent a hydrogen atom, a hydroxymethyl group, or a methoxymethyl group,
A and B each independently represent an alkylene group having 1 or 2 carbon atoms and optionally substituted with a benzene ring or an alkyl group having 1 to 10 carbon atoms, or a single bond,
X represents an alkylene group having 1 or 2 carbon atoms and optionally substituted with a benzene ring or an alkyl group having 1 to 10 carbon atoms, an arylene group, or a single bond, l and m each independently represent 1 or 2,
n1 to n4 are each independently 0 or 1, and satisfy ((n1+n2)l+(n3+n4)m)/(2l+2m)≥0.3, with the proviso that not all of A, B and X is a single bond.

Examples of the alkylene group having 1 or 2 carbon atoms include a methylene group and an ethylene group.

Examples of the alkyl group having 1 to 10 carbon atoms and optionally bonded to the alkylene group include a methyl group, an ethyl group, a n-propyl group, an i-propyl group, a cyclopropyl group, a n-butyl group, an i-butyl group, a s-butyl group, a t-butyl group, a cyclobutyl group, a 1-methyl-cyclopropyl group, a 2-methyl-cyclopropyl group, a n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group. Two of these substituents may be bonded to the same carbon atom, or may be bonded to each other to form a ring.

Examples of the arylene group include a phenyl group, a naphthalene group, and an anthracenyl group.

In Formula (1), n1 to n4 are each independently 0 or 1, and satisfy ((n1+n2)l+(n3+n4)m)/(2l+2m)≥0.3. From the viewpoint of obtaining a resist underlayer film having high hardness, ((n1+n2)l+(n3+n4)m)/(2l+2m) is preferably more than 0.3, more preferably 0.4 or more, still more preferably 0.5 or more, and most preferably 1.

The value of the mathematical expression ((n1+n2)l+(n3+n4)m)/(2l+2m) expressed in percentage is defined as a methylolation ratio, and the methylolation ratio is a value of the number of actually bonded methylol groups relative to the number of methylol groups that can be theoretically bonded to the carbon adjacent to the hydroxy group on the aromatic ring, calculated by a 1H-NMR area ratio. The methylolation ratio can be determined by calculation from a 1H-NMR area ratio between hydrogen atoms of methylol groups and arbitrary hydrogen atoms other than those of methylol groups (excluding hydrogen atoms of hydroxy groups).

Examples of the compound (P) include, but are not limited to, the following compounds.

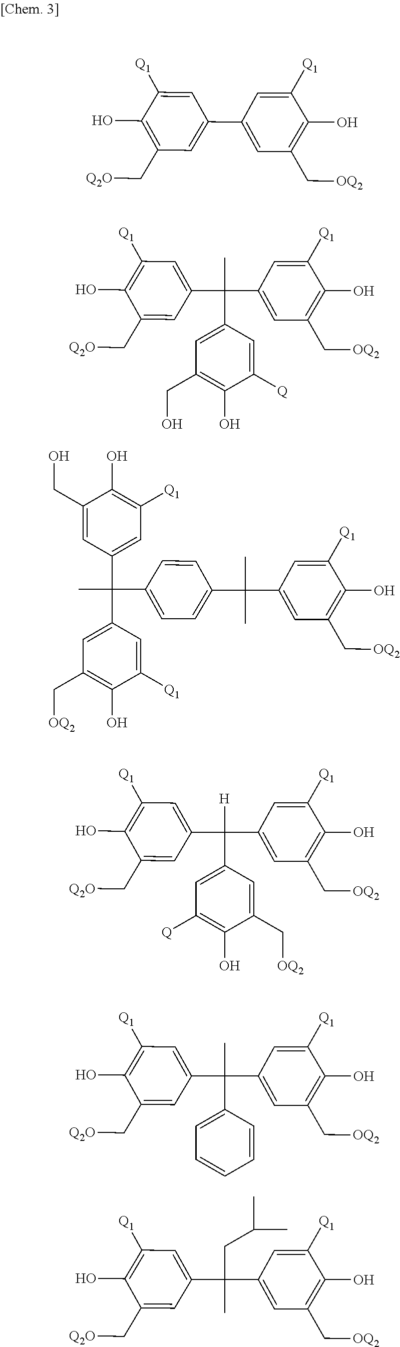

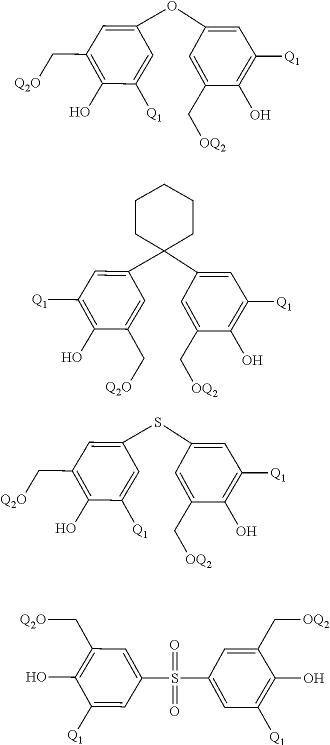

Each of Q₁ and Q is a hydroxymethyl group or a methoxymethyl group, and may be a hydrogen atom as long as ((n1+n2)l+(n3+n4)m)/(2l+2m)≥0.3 in Formula (1) above is satisfied. Q₂ is a hydrogen atom or a methyl group.

For example, the compound (P) can be synthesized by reacting a compound of the following Formula (2) with formaldehyde in the presence of a base in an aqueous solution. If necessary, a methoxymethyl group can be introduced by further reacting a compound that reacts with a hydroxymethyl group to give a methoxymethyl group.

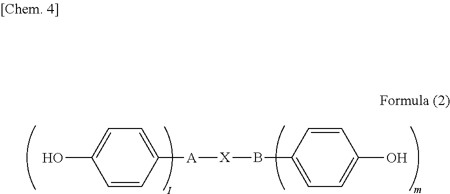

The groups A, B and X are as defined for Formula (1), and the numbers 1 and m are as defined for Formula (1).

As the compound (P), commercial products shown below may also be used.

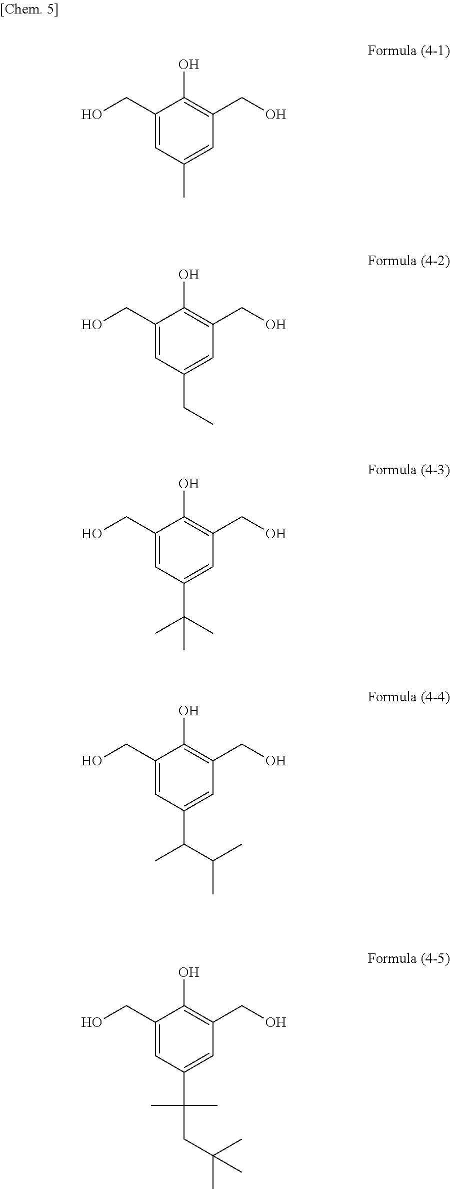 [SMILES: Cc1cc(CO)c(O)c(CO)c1 ; CCc1cc(CO)c(O)c(CO)c1 ; CC(C)(C)c1cc(CO)c(O)c(CO)c1 ; CC(C)C(C)c1cc(CO)c(O)c(CO)c1 ; CC(C)(C)CC(C)(C)c1cc(CO)c(O)c(CO)c1]

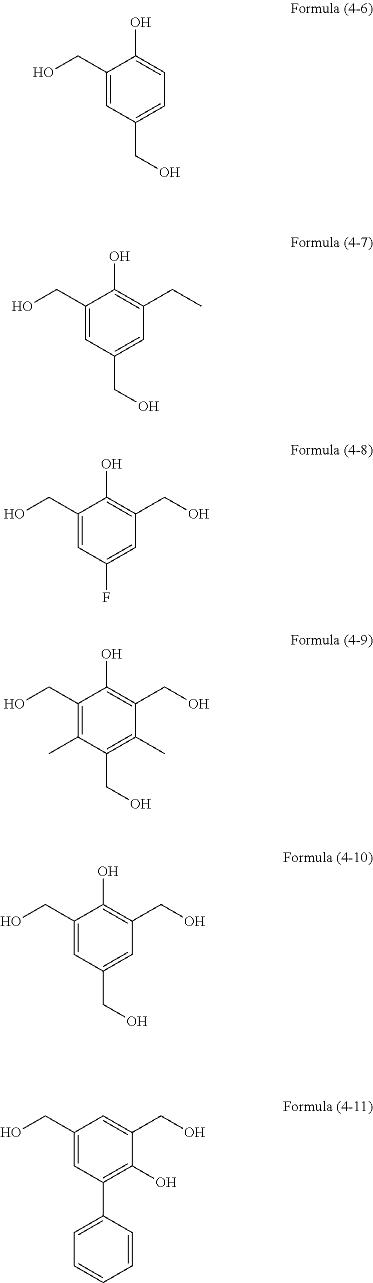 [SMILES: OCc1ccc(O)c(CO)c1 ; CCc1cc(CO)cc(CO)c1O ; OCc1cc(F)cc(CO)c1O ; Cc1c(CO)c(C)c(CO)c(O)c1CO ; OCc1cc(CO)c(O)c(CO)c1 ; OCc1cc(CO)c(O)c(-c2ccccc2)c1]

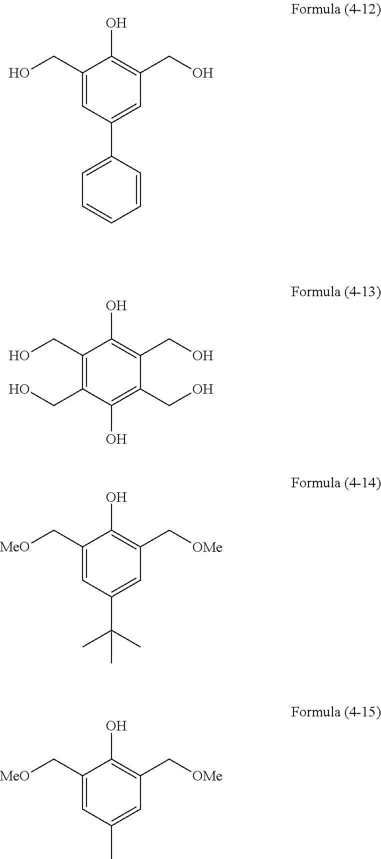 [SMILES: OCc1cc(-c2ccccc2)cc(CO)c1O ; OCc1c(O)c(CO)c(CO)c(O)c1CO ; COCc1cc(C(C)(C)C)cc(COC)c1O ; COCc1cc(C)cc(COC)c1O]

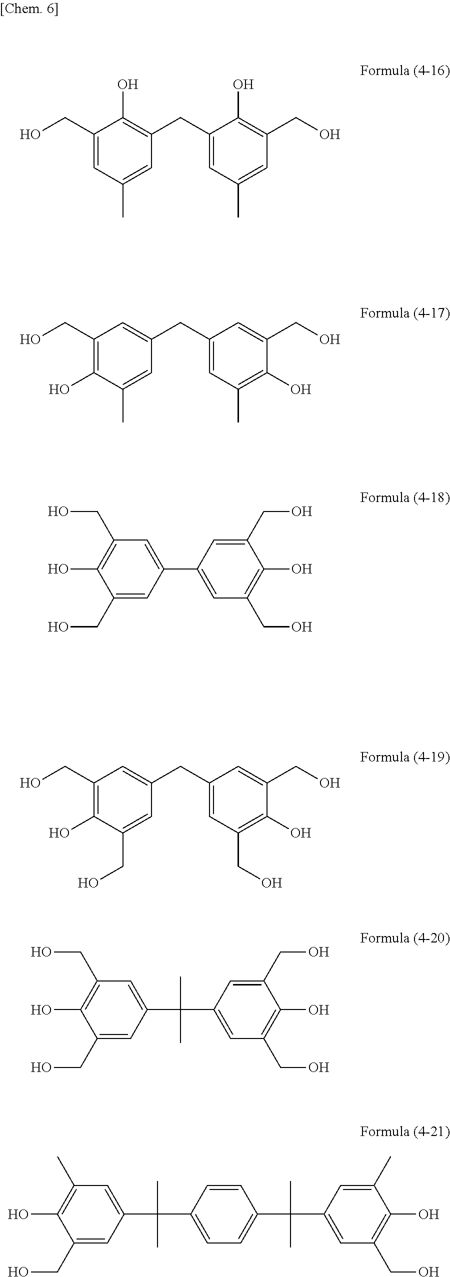 [SMILES: Cc1cc(CO)c(O)c(Cc2cc(C)cc(CO)c2O)c1 ; Cc1cc(Cc2cc(C)c(O)c(CO)c2)cc(CO)c1O ; OCc1cc(-c2cc(CO)c(O)c(CO)c2)cc(CO)c1O ; OCc1cc(Cc2cc(CO)c(O)c(CO)c2)cc(CO)c1O ; CC(C)(c1cc(CO)c(O)c(CO)c1)c1cc(CO)c(O)c(CO)c1 ; Cc1cc(C(C)(C)c2ccc(C(C)(C)c3cc(C)c(O)c(CO)c3)cc2)cc(CO)c1O]

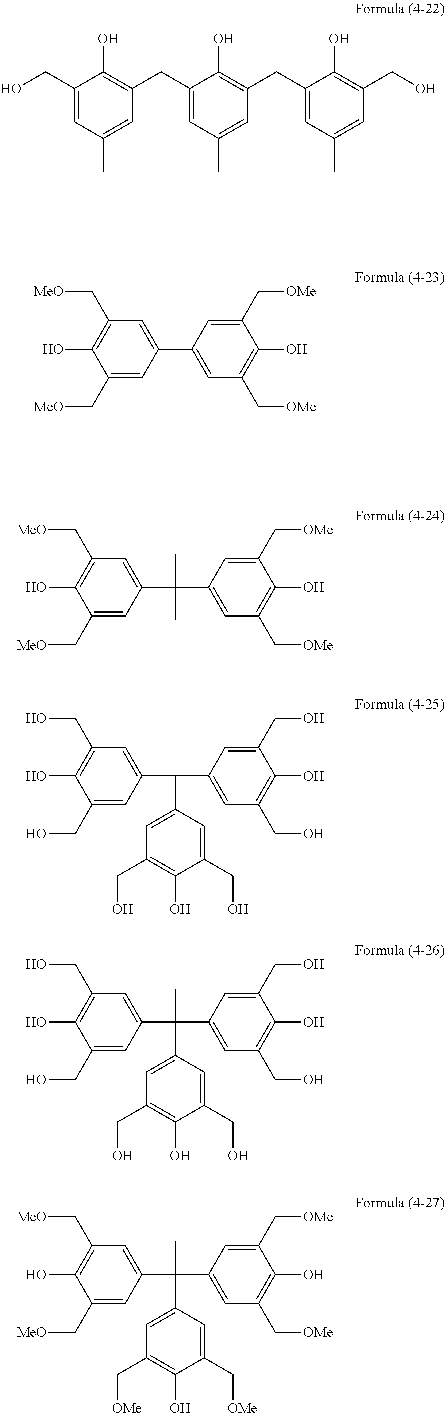 [SMILES: Cc1cc(CO)c(O)c(Cc2cc(C)cc(Cc3cc(C)cc(CO)c3O)c2O)c1 ; COCc1cc(-c2cc(COC)c(O)c(COC)c2)cc(COC)c1O ; COCc1cc(C(C)(C)c2cc(COC)c(O)c(COC)c2)cc(COC)c1O ; OCc1cc(C(c2cc(CO)c(O)c(CO)c2)c2cc(CO)c(O)c(CO)c2)cc(CO)c1O ; CC(c1cc(CO)c(O)c(CO)c1)(c1cc(CO)c(O)c(CO)c1)c1cc(CO)c(O)c(CO)c1 ; COCc1cc(C(C)(c2cc(COC)c(O)c(COC)c2)c2cc(COC)c(O)c(COC)c2)cc(COC)c1O]

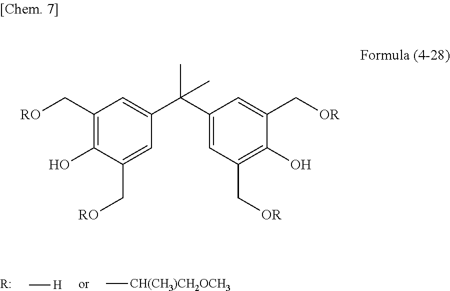

The above compounds are available as a product from Asahi Yukizai Corporation, or Honshu Chemical Industry Co., Ltd. For example, of the cross-linking agents above, the compound of formula (4-23) is available as TMOM-BP (trade name) from Honshu Chemical Industry Co., Ltd., the compound of formula (4-24) is available as TM-BIP-A (trade name) from Asahi Yukizai Corporation, and the compound of formula (4-28) is available as PGME-BIP-A (trade name) from Finechem Co., Ltd.

### [Solvent]

The resist underlayer film-forming composition of the present invention may be prepared by dissolving the above-mentioned components in an appropriate solvent, and is used in the form of a homogeneous solution.

Examples of the solvent include ethylene glycol monomethyl ether, ethylene glycol monoethyl ether, diethylene glycol monomethyl ether, diethylene glycol monoethyl ether, propylene glycol, propylene glycol monomethyl ether, propylene glycol monopropyl ether, propylene glycol monomethyl ether acetate, propylene glycol propyl ether acetate, methyl cellosolve acetate, ethyl cellosolve acetate, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, and N-methylpyrrolidone.

Further, a high-boiling-point solvent having a boiling point of 180° C. or higher may also be used. Specific examples of the high-boiling-point organic solvent include 1-octanol, 2-ethylhexanol, 1-nonanol, 1-decanol, 1-undecanol, ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, glycerin, n-nonyl acetate, ethylene glycol monohexyl ether, ethylene glycol mono-2-ethylhexyl ether, ethylene glycol monophenyl ether, ethylene glycol monobenzyl ether, diethylene glycol monoethyl ether, diethylene glycol monoisopropyl ether, diethylene glycol mono-n-butyl ether, diethylene glycol monoisobutyl ether, diethylene glycol monohexyl ether, diethylene glycol monophenyl ether, diethylene glycol monobenzyl ether, diethylene glycol diethyl ether, diethylene glycol dibutyl ether, diethylene glycol butyl methyl ether, triethylene glycol dimethyl ether, triethylene glycol monomethyl ether, triethylene glycol-n-butyl ether, triethylene glycol butyl methyl ether, triethylene glycol diacetate, tetraethylene glycol dimethyl ether, dipropylene glycol monomethyl ether, dipropylene glycol mono-n-propyl ether, dipropylene glycol mono-n-butyl ether, tripropylene glycol dimethyl ether, tripropylene glycol monomethyl ether, tripropylene glycol mono-n-propyl ether, tripropylene glycol mono-n-butyl ether, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, triacetin, propylene glycol diacetate, dipropylene glycol monomethyl ether acetate, dipropylene glycol methyl-n-propyl ether, dipropylene glycol methyl ether acetate, 1,4-butanediol diacetate, 1,3-butylene glycol diacetate, 1,6-hexanediol diacetate, triethylene glycol diacetate, γ-butyrolactone, dihexyl malonate, diethyl succinate, dipropyl succinate, dibutyl succinate, dihexyl succinate, dimethyl adipate, diethyl adipate, and dibutyl adipate.

These solvents may be used each alone, or in combination of two or more thereof. The proportion of the solid content excluding the organic solvent from the composition is, for example, within the range of 0.5% by mass to 30% by mass, and preferably 0.8% by mass to 15% by mass.

The following compounds described in WO 2018/131562 A1 may also be used:

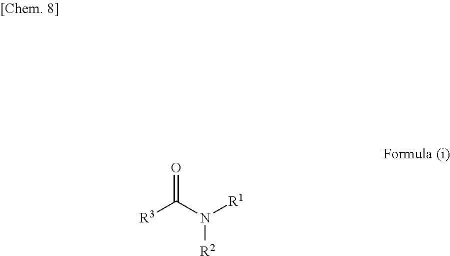

wherein R¹, R² and R³ each represent a hydrogen atom, an oxygen atom, a sulfur atom, or an alkyl group having 1 to 20 carbon atoms and optionally interrupted by an amide bond, which may be the same or different, and may be linked together to form a ring structure.

Examples of the alkyl group having 1 to 20 carbon atoms include a linear or branched alkyl group optionally having a substituent, and examples thereof include a methyl group, an ethyl group, a n-propyl group, an isopropyl group, a n-butyl group, a sec-butyl group, a tert-butyl group, a n-pentyl group, an isopentyl group, a neopentyl group, a n-hexyl group, an isohexyl group, a n-heptyl group, a n-octyl group, a cyclohexyl group, a 2-ethylhexyl group, a n-nonyl group, an isononyl group, a p-tert-butylcyclohexyl group, a n-decyl group, a n-dodecylnonyl group, an undecyl group, a dodecyl group, a tridecyl group, a tetradecyl group, a pentadecyl group, a hexadecyl group, a heptadecyl group, an octadecyl group, nonadecyl group, and an eicosyl group. An alkyl group having 1 to 12 carbon atoms is preferable, an alkyl group having 1 to 8 carbon atoms is more preferable, and an alkyl group having 1 to 4 carbon atoms is still more preferable.

Examples of the alkyl group having 1 to 20 carbon atoms and interrupted by an oxygen atom, a sulfur atom or an amide bond include those containing a structural unit-CH₂—O—, —CH₂—S—, —CH₂—NHCO— or —CH₂—CONH—. There may be one unit or two or more units of —O—, —S—, —NHCO— or —CONH— in the alkyl group. Specific examples of the alkyl group having 1 to 20 carbon atoms interrupted by the —O—, —S—, —NHCO— or —CONH— unit include a methoxy group, an ethoxy group, a propoxy group, a butoxy group, a methylthio group, an ethylthio group, a propylthio group, a butylthio group, a methylcarbonylamino group, an ethylcarbonylamino group, a propylcarbonylamino group, a butylcarbonylamino group, a methylaminocarbonyl group, an ethylaminocarbonyl group, a propylaminocarbonyl group, a butylaminocarbonyl group, and a methyl group, an ethyl group, a propyl group, a butyl group, a pentyl group, a hexyl group, a heptyl group, an octyl group, a nonyl group, a decyl group, a dodecyl group or an octadecyl group substituted with a methoxy group, an ethoxy group, a propoxy group, a butoxy group, a methylthio group, an ethylthio group, a propylthio group, a butylthio group, a methylcarbonylamino group, an ethylcarbonylamino group, a methylaminocarbonyl group, an ethylaminocarbonyl group or the like. A methoxy group, an ethoxy group, a methylthio group, and an ethylthio group are preferable, and a methoxy group and an ethoxy group are more preferable.

These solvents have a relatively high boiling point, and thus are effective for imparting a high filling property and a high planarization property to the resist underlayer film-forming composition.

Specific examples of preferred compounds represented by the formula (i) are shown below.

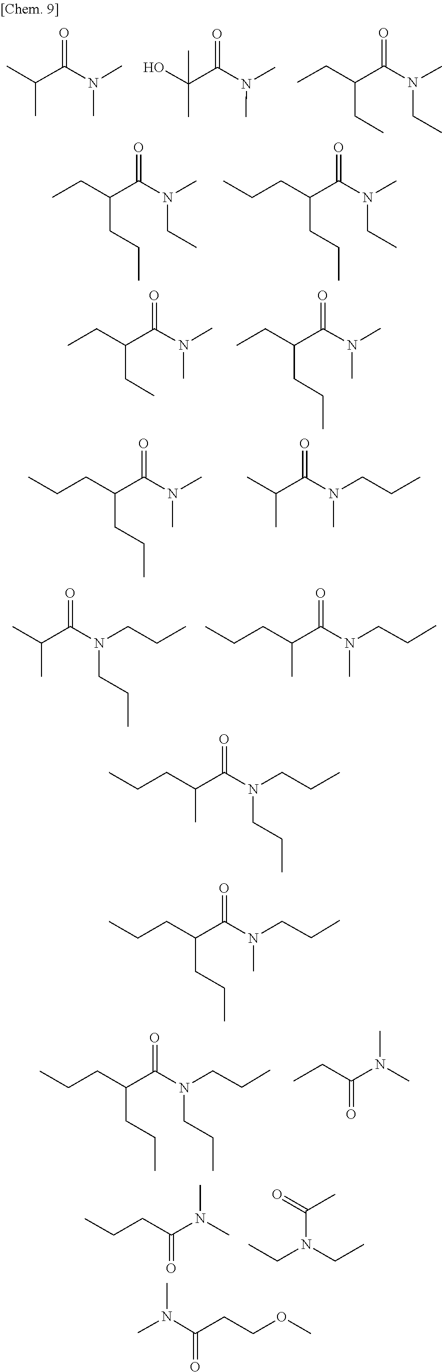

Of the above, 3-methoxy-N,N-dimethylpropionamide, N,N-dimethylisobutyramide, and compounds represented by the following formula are preferable.

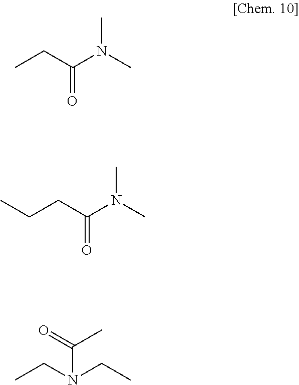

3-Methoxy-N,N-dimethylpropionamide and N,N-dimethylisobutyramide are particularly preferable as compounds represented by formula (i).

These solvents may be used each alone, or in combination of two or more thereof. Of these solvents, those having a boiling point of 160° C. or higher are preferable, and propylene glycol monomethyl ether, propylene glycol monomethyl ether acetate, ethyl lactate, butyl lactate, cyclohexanone, 3-methoxy-N,N-dimethylpropionamide, N,N-dimethylisobutyramide, 2,5-dimethylhexane-1,6-diyl diacetate (DAH; cas, 89182-68-3), 1,6-diacetoxyhexane (cas, 6222-17-9), and the like are preferable. In particular, propylene glycol monomethyl ether, propylene glycol monomethyl ether acetate, and N,N-dimethylisobutyramide are preferable.

### [Optional Components]

The resist underlayer film-forming composition of the present invention may further contain at least one of an acid and/or an acid generator, a thermal acid generator, and a surfactant as optional components.

(Acid and/or Acid Generator)

The resist underlayer film-forming composition according to the present invention may contain an acid and/or an acid generator.

Examples of the acid include p-toluenesulfonic acid, trifluoromethanesulfonic acid, pyridinium p-toluenesulfonic acid, pyridinium phenolsulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, carboxylic acid compounds such as citric acid, benzoic acid, hydroxybenzoic acid and naphthalenecarboxylic acid, and inorganic acids such as hydrochloric acid, sulfuric acid, nitric acid and phosphoric acid.

The acids may be used each alone or in combination of two or more thereof. The blending amount is typically within the range of 0.0001 to 20% by mass, preferably 0.0005 to 10% by mass, and more preferably 0.01 to 5% by mass based on a total solid content.

Examples of the acid generator include a thermal acid generator and a photoacid generator.

Examples of the thermal acid generator include 2,4,4,6-tetrabromocyclohexadienone, benzoin tosylate, 2-nitrobenzyl tosylate, K-PURE [registered trademark] CXC-1612, CXC-1614, TAG-2172, TAG-2179, TAG-2678, TAG2689 and TAG2700 (manufactured by King Industries, Inc.), and SI-45, SI-60, SI-80, SI-100, SI-110 and SI-150 (manufactured by Sanshin Chemical Industry Co., Ltd.), as well as quaternary ammonium salts of trifluoroacetic acid and organic sulfonic acid alkyl esters.

Examples of the onium salt compound include iodonium salt compounds such as diphenyliodonium hexafluorophosphate, diphenyliodonium trifluoromethanesulfonate, diphenyliodonium nonafluoro-normal-butanesulfonate, diphenyliodonium perfluoro-normal-octanesulfonate, diphenyliodonium camphorsulfonate, bis(4-tert-butylphenyl)iodonium camphorsulfonate and bis(4-tert-butylphenyl)iodonium trifluoromethanesulfonate, and sulfonium salt compounds such as triphenylsulfonium hexafluoroantimonate, triphenylsulfonium nonafluoro-normal-butanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generators may be used each alone or in combination of two or more thereof.

When the acid generator is used, the proportion thereof is within the range of 0.01 to 10 parts by mass, 0.1 to 8 parts by mass, or 0.5 to 5 parts by mass based on 100 parts by mass of the solid content of the resist underlayer film-forming composition.

### (Surfactant)

The resist underlayer film-forming composition of the present invention may further contain a surfactant. Examples of the surfactant include nonionic surfactants such as polyoxyethylene alkyl ethers such as polyoxyethylene lauryl ether, polyoxyethylene stearyl ether, polyoxyethylene cetyl ether and polyoxyethylene oleyl ether, polyoxyethylene alkyl aryl ethers such as polyoxyethylene octylphenyl ether and polyoxyethylene nonylphenyl ether, polyoxyethylene/polyoxypropylene block copolymers, sorbitan fatty acid esters such as sorbitan monolaurate, sorbitan monopalmitate, sorbitan monostearate, sorbitan monooleate, sorbitan trioleate and sorbitan tristearate, polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate and polyoxyethylene sorbitan stearate, fluorine-based surfactants such as EFTOP [registered trademark] EF301, EFTOP EF303, EFTOP EF352 (manufactured by Mitsubishi Materials Electronic Chemicals Co., Ltd.), MEGAFACE [registered trademark] F171, MEGAFACE F173, MEGAFACE R-30, MEGAFACE R-30N, MEGAFACE R-40, MEGAFACE R-40-LM (manufactured by DIC Corporation), Fluorad FC430, Fluorad FC431 (manufactured by Sumitomo 3M), and AsahiGuard [registered trademark] AG710, Surflon [registered trademark] S-382, Surflon SC101, Surflon SC102, Surflon SC103, Surflon SC104, Surflon SC105, Surflon SC106 (manufactured by Asahi Glass Co., Ltd.), and organosiloxane polymer KP341 (manufactured by Shin-Etsu Chemical Co., Ltd.). These surfactants may be used each alone or in combination. The content ratio of the surfactant is, for example, within the range of 0.01% by mass to 5% by mass based on the solid content excluding the below-mentioned solvents from the resist underlayer film-forming composition of the present invention.

### (Light Absorbing Agent)

As light absorbing agents, commercially available light absorbing agents described in “Technology and Market of Industrial Dyes” (CMC Publishing Co., Ltd.) and “Dyestuff Handbook” (edited by The Society Of Synthetic Organic Chemistry, Japan), for example, C.I. Disperse Yellow 1, 3, 4, 5, 7, 8, 13, 23, 31, 49, 50, 51, 54, 60, 64, 66, 68, 79, 82, 88, 90, 93, 102, 114 and 124; C.I. Disperse Orange 1, 5, 13, 25, 29, 30, 31, 44, 57, 72 and 73; C.I. Disperse Red 1, 5, 7, 13, 17, 19, 43, 50, 54, 58, 65, 72, 73, 88, 117, 137, 143, 199 and 210; C.I. Disperse Violet 43; C.I. Disperse Blue 96; C.I. Fluorescent Brightening Agent 112, 135 and 163; C.I. Solvent Orange 2 and 45; C.I. Solvent Red 1, 3, 8, 23, 24, 25, 27 and 49; C.I. Pigment Green 10; C.I. Pigment Brown 2 and the like may be preferably used. The light absorbing agent is typically blended in a ratio of 10% by mass or less, preferably 5% by mass or less based on the total solid content of the resist underlayer film-forming composition.

### (Rheology Modifier)

A rheology modifier is added mainly for the purpose of improving the fluidity of the resist underlayer film-forming composition, and improving the thickness uniformity of the resist underlayer film and enhancing the filling property of the resist underlayer film-forming composition to the inside of a hole particularly in a baking step. Specific examples thereof include phthalic acid derivatives such as dimethyl phthalate, diethyl phthalate, diisobutyl phthalate, dihexyl phthalate and butyl isodecyl phthalate, adipic acid derivatives such as dinormal-butyl adipate, diisobutyl adipate, diisooctyl adipate and octyl decyl adipate, maleic acid derivatives such as dinormal-butyl maleate, diethyl maleate and dinonyl maleate, oleic acid derivatives such as methyl oleate, butyl oleate and tetrahydrofurfuryl oleate, and stearic acid derivatives such as normal-butyl stearate and glyceryl stearate. These rheology modifiers are typically blended in a ratio of less than 30% by mass based on the total solid content of the resist underlayer film-forming composition.

### (Bonding Auxiliary)

The bonding auxiliary is added mainly for the purpose of improving adhesion between a substrate or a resist and the resist underlayer film-forming composition, and preventing the resist from peeling particularly in development. Specific examples thereof include chlorosilanes such as trimethylchlorosilane, dimethylmethylolchlorosilane, methyldiphenylchlorosilane and chloromethyldimethylchlorosilane, alkoxysilanes such as trimethylmethoxysilane, dimethyldiethoxysilane, methyldimethoxysilane, dimethylmethylolethoxysilane, diphenyldimethoxysilane and phenyltriethoxysilane, silazanes such as hexamethyldisilazane, N,N′-bis(trimethylsilyl)urea, dimethyltrimethylsilylamine and trimethylsilyl imidazole, silanes such as methyloltrichlorosilane, γ-chloropropyltrimethoxysilane, γ-aminopropyltriethoxysilane and γ-glycidoxypropyltrimethoxysilane, heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole and mercaptopyrimidine, and urea or thiourea compounds such as 1,1-dimethylurea and 1,3-dimethylurea. These bonding auxiliaries are typically blended in a ratio of less than 5% by mass, and preferably less than 2% by mass based on the total solid content of the resist underlayer film-forming composition.

The solid content of the resist underlayer film-forming composition according to the present invention is typically within the range of 0.1 to 70% by mass, and preferably 0.1 to 60% by mass. The solid content is a content ratio of all components excluding the solvents from the resist underlayer film-forming composition. The proportion of the polymer in the solid content is preferably within the range of 1 to 100% by mass, more preferably 1 to 99.9% by mass, more preferably 50 to 99.9% by mass, more preferably 50 to 95% by mass, and more preferably 50 to 90% by mass.

One of the methods for evaluating whether the resist underlayer film-forming composition is in the form of a homogeneous solution is observation of the ability to pass through a specific microfilter, and the resist underlayer film-forming composition according to the present invention passes through a microfilter having a pore size of 0.1 μm, and is shown to be in the form of a homogeneous solution.

Examples of the microfilter material include fluorine-based resins such as PTFE (polytetrafluoroethylene) and PFA (tetrafluoroethylene/perfluoroalkyl vinyl ether copolymer), PE (polyethylene), UPE (ultra-high molecular weight polyethylene), PP (polypropylene), PSF (polysulfone), PES (polyether sulfone), and nylon, with PTFE (polytetrafluoroethylene) being preferable.

### [Resist Underlayer Film]

A resist underlayer film may be formed in the following manner using the resist underlayer film-forming composition according to the present invention.

The resist underlayer film-forming composition of the present invention is applied onto a substrate for use in production of a semiconductor device (for example, a silicon wafer substrate, a silicon/silicon dioxide-coated substrate, a silicon nitride substrate, a glass substrate, an ITO substrate, a polyimide substrate or a low-dielectric-constant material (low-k material)-coated substrate) by an appropriate application method with as a spinner, a coater or the like, and then baked with a heating unit such as a hot plate to form a resist underlayer film. As baking conditions, a baking temperature of 80° C. to 600° C. and a baking time of 0.3 to 60 minutes are appropriately selected. Preferably, the baking temperature is within the range of 150° C. to 350° C., and the baking time is within the range of 0.5 to 2 minutes. As the atmospheric gas during baking, air may be used, or an inert gas such as nitrogen or argon may be used. The baking may be performed such that the temperature and the baking time in the first stage differ from those in the second stage. Here, the thickness of the underlayer film formed is, for example, 10 to 1000 nm, 20 to 500 nm, 30 to 400 nm, or 50 to 300 nm. In addition, when as the substrate, a quartz substrate is used, a replica (mold replica) of a quartz imprint mold may be prepared.

In addition, an adhesion layer and/or a silicone layer containing Si in an amount of 99% by mass or less or 50% by mass or less may be formed on the resist underlayer film according to the present invention by application or vapor deposition. For example, there is a method in which an adhesion layer described in JP 2013-202982 A or JP 5827180 B or a silicon-containing resist underlayer film (inorganic resist underlayer film) forming composition described in WO2009/104552A1 is formed by spin coating, and a Si-based inorganic material film may be formed by a CVD method or the like.

In addition, by applying the resist underlayer film-forming composition according to the present invention onto a semiconductor substrate including a portion having a level difference and a portion having no level difference (the so-called stepped substrate), followed by baking, a resist underlayer film may be formed in which a level difference between the portion having a level difference and the portion having no level difference is in the range of 3 to 70 nm.

### [Method for Producing Semiconductor Device]

A method for producing a semiconductor device according to the present invention includes the steps of: forming a resist underlayer film using the resist underlayer film-forming composition according to the present invention; forming a resist film on the formed resist underlayer film; forming a resist pattern by irradiating the formed resist film with a light or electron beam and developing the irradiated film; etching the resist underlayer film via the formed resist pattern to make a patterned resist underlayer film; and processing the semiconductor substrate via the patterned resist underlayer film.

A method for producing a semiconductor device according to the present invention includes the steps of: forming a resist underlayer film using the resist underlayer film-forming composition according to the present invention; forming a hard mask on the formed resist underlayer film; forming a resist film on the formed hard mask; forming a resist pattern by irradiating the formed resist film with a light or electron beam and developing the irradiated film; etching the hard mask via the formed resist pattern to make a patterned hard mask; etching the resist underlayer film via the patterned hard mask to make a patterned resist underlayer film; and processing the semiconductor substrate via the patterned resist underlayer film.

The step of forming a resist underlayer film using the resist underlayer film-forming composition according to the present invention is as described above.

On the resist underlayer film formed in the above-described step, an organopolysiloxane film may be formed as a second resist underlayer film, followed by formation of a resist pattern thereon. The second resist underlayer film may be a SiON film or a SiN film formed by a vapor deposition method such as CVD or PVD.

Further, an antireflection film (BARC) may be formed as a third resist underlayer film on the second resist underlayer film, and the third resist underlayer film may be a resist shape correction film having no antireflection ability.

In the step of forming a resist pattern, exposure is performed through a mask (reticle) for forming a predetermined pattern or directly by lithography. As an exposure source, for example, a g-ray, an i-ray, a KrF excimer laser, an ArF excimer laser, EUV, or an electron beam may be used. After the exposure, post exposure bake is performed if necessary. Thereafter, development is performed with a developer (for example, a 2.38% by mass tetramethylammonium hydroxide aqueous solution), and rinsing is performed with a rinse liquid or pure water to remove the used developer. Thereafter, post-baking is performed to dry the resist pattern and enhance adhesion to the base.

The etching step after formation of the resist pattern is carried out by dry etching. Examples of the etching gas for use in dry etching include CHF₃, CF₄ and C₂F₆ for the second resist underlayer film (organopolysiloxane film), O₂, N₂O and NO₂ for the first resist underlayer film formed from the resist underlayer film-forming composition of the present invention, and CHF₃, CF₄ and C₂F₆ for the surface having a level difference or a concave portion and/or a convex portion. Further, these gases may be mixed with argon, nitrogen or carbon dioxide, and used.

### [Formation of Resist Underlayer Film by Nanoimprinting Method]

The step of forming a resist underlayer film may also be carried out by a nanoimprinting method. The method includes the steps of applying a curable composition onto the formed resist underlayer film; bringing the curable composition and a mold into contact with each other, irradiating the curable composition with a light or electron beam to obtain a cured film, and separating the cured film and the mold.

In the mold release step of the optical nanoimprinting technique, adhesion between the resist composition and the base material is critical. This is because if adhesion between the resist composition and the base material is low, a pattern-peeling defect in which a part of a photocured product obtained by curing the resist composition peels while adhering to the mold may occur in separation of the mold in the mold release step. As a technique for improving adhesion between a resist composition and a base material, a technique has been proposed in which an adhesion layer that is a layer for bringing the resist composition and the base material into close contact with each other is formed between the resist composition and the base material.

In addition, a high-etching resistance layer may be used for pattern formation in nanoimprinting. As a material for the high-etching resistance layer, an organic material and a silicon-based material are commonly used. Further, an adhesion layer or a silicone layer containing Si may be formed on a nanoimprinting resist underlayer film by application or vapor deposition. In the case where the adhesion layer and the silicone layer containing Si are hydrophobic and exhibit a high pure water contact angle, it is expected that when the underlayer film also is hydrophobic and exhibits a high pure water contact angle, adhesion between the films is enhanced, so that peeling is unlikely to occur. On the other hand, in the case where the adhesion layer and the silicone layer are hydrophilic and exhibit a low pure contact angle, it is expected that when the underlayer film also is hydrophilic and exhibits a low pure contact angle, adhesion between the films is enhanced, so that peeling is unlikely to occur.

In addition, He, H₂, N₂, air and the like may be used depending on the characteristics of the adhesion film, the silicone layer and the underlayer film.

The polymer (X) according to the present invention exhibits a desired pure water contact angle not only during low-temperature baking but also during high-temperature baking, and exhibits a desired pure water contact angle when a cross-linking agent, an acid catalyst and a surfactant are mixed to obtain a material. Thus, it is possible to enhance adhesion to the upper layer film, and exhibition of good permeability to gases such as He, H₂, N₂ and air may be exhibited. Further, the polymer (X) according to the present invention exhibits a good planarization property, and may be adjusted to an optical constant and an etching rate suitable for the process by changing the molecular skeleton.

### (Curable Composition)

The photoresist formed on the resist underlayer film is not particularly limited as long as it is sensitive to the light used for exposure. Any of a negative photoresist and a positive photoresist may be used. Examples of the photoresist include positive photoresists formed of a novolak resin and 1,2-naphthoquinone diazide sulfonic acid ester, chemically amplified photoresists formed of a binder having a group that is decomposed by an acid to increase the alkali dissolution rate, and a photoacid generator, chemically amplified photoresists formed of a low-molecular-weight compound that is decomposed by an acid to increase the alkali dissolution rate of the photoresist, an alkali-soluble binder and a photoacid generator, and chemically amplified photoresists formed of a binder having a group that is decomposed by an acid to increase the alkali dissolution rate, a low-molecular-weight compound that is decomposed by an acid to increase the alkali dissolution rate of the photoresist, and a photoacid generator. Examples thereof include APEX-E (trade name) manufactured by Shipley Company, PAR710 (trade name) manufactured by Sumitomo Chemical Industry Co., Ltd., and SEPR430 (trade name) manufactured by Shin-Etsu Chemical Co., Ltd. In addition, for example, fluorine atom-containing polymer-based photoresists described in Proc. SPIE, Vol. 3999, 330-334 (2000), Proc. SPIE, Vol. 3999, 357-364 (2000), and Proc. SPIE, Vol. 3999, 365-374 (2000) can be exemplified.

### (Step of Applying Curable Composition)

The present step is a step of applying a curable composition onto a resist underlayer film formed by the method for producing a resist underlayer film according to the present invention. As a method for applying a curable composition, for example, an inkjet method, a dip coating method, an air knife coating method, a curtain coating method, a wire bar coating method, a gravure coating method, an extrusion coating method, a spin coating method, a slit scanning method, or the like may be used. An inkjet method is suitable for applying the curable composition as droplets, and a spin coating method is suitable for applying the curable composition. In the present step, it is also possible to form, on the resist underlayer film, an adhesion layer and/or a silicone layer containing Si in an amount of 99% by mass or less or 50% by mass or less by application or vapor deposition, onto which the curable composition is applied.

(Step of Bringing Curable Composition and Mold into Contact with Each Other)

In the present step, the curable composition and a mold are brought into contact with each other. For example, the curable composition that is liquid and a mold having an original pattern whose pattern shape is transferred are brought into contact with each other to form a liquid film with the curable composition filling concave portions of a fine pattern on the surface of the mold.

It is recommended to use a mold having using a light transmissive material as a base material in consideration of a step of irradiation with a light or electron beam which will be described later. Specifically, the mold base material is preferably an optically transparent resin such as glass, quartz, PMMA or a polycarbonate resin, a transparent metallized film, a flexible film of polydimethylsiloxane or the like, a photocured film, a metal film, or the like. The mold base material is more preferably quartz because it has a small thermal expansion coefficient, so that little pattern distortion occurs.

The fine pattern on the surface of the mold preferably has a pattern height of 4 nm or more and 200 nm or less. A certain pattern height is required for improving the accuracy of processing of the substrate. The lower the pattern height, the lower the force to peel the mold from the cured film in the step of separating the cured film and the mold, which will be described later, and the smaller the number of defects remaining on the mask side due to tear of the resist pattern. It is recommended that in view of the above, an appropriately balanced pattern height be selected and adopted.

In addition, adjacent resist patterns may come into contact with each other due to elastic deformation of the resist patterns by impact in peeling of the mold, resulting in adhesion or damage of the resist patterns. This may be avoided by making the pattern height equal to or less than about two times the pattern width (an aspect ratio of 2 or less).

It is also possible to perform surface treatment on the mold in advance for improving the peeling property between the curable composition and the surface of the mold. Examples of the surface treatment method include a method in which a mold release agent is applied to the surface of the mold to form a mold release agent layer thereon. Examples of the mold release agent include silicone-based mold release agents, fluorine-based mold release agents, hydrocarbon-based mold release agents, polyethylene-based mold release agents, polypropylene-based mold release agents, paraffin-based mold release agents, montan-based mold release agents, and carnauba-based mold release agents. Fluorine-based mold release agents and hydrocarbon-based mold release agents are preferable. Examples of the commercially product include OPTOOL (registered trademark) DSX manufactured by Daikin Industries, Ltd. The mold release agents may be used each alone or in combination of two or more thereof.

In the present step, the pressure applied to the curable composition in bringing the mold and the curable composition into contact with each other is not particularly limited. A pressure of 0 MPa or more and 100 MPa or less is recommended. The pressure is preferably 0 MPa or more and 50 MPa or less, 30 MPa or less, or 20 MPa or less.

When the pre-spreading of droplets of the curable composition proceeds in a previous step (step of applying the curable composition), the spreading of the curable composition in the present step is quickly completed. As a result, the time of contact between the mold and the curable composition may be reduced. The contact time is not particularly limited, and is preferably 0.1 seconds or more and 600 seconds or less, 3 seconds or less, or 1 second or less. If the contact time is excessively short, spreading and filling may become insufficient, resulting in occurrence of a defect called an unfilled state defect.

The present step may be carried out under any conditions of an air atmosphere, a reduced pressure atmosphere and an inert gas atmosphere, and is preferably carried out under a pressure of 0.0001 atm or more and 10 atm or less. It is recommended to carry out the step under a reduced pressure atmosphere or an inert gas atmosphere for preventing the influence of oxygen and moisture on the curing reaction. Specific examples of the inert gas that may be used to establish an inert gas atmosphere include nitrogen, carbon dioxide, helium, argon, CFC, HCFC, HFC or mixtures thereof.

The present step may be carried out under an atmosphere containing a condensable gas (hereinafter, referred to as a “condensable gas atmosphere”). In the present specification, the term “condensable gas” refers to a gas which, when, together with the curable composition, filling gaps between the substrate, and the mold and concave portions of the fine pattern formed on the mold, is condensed and liquefied by a capillary pressure generated during the filling. The condensable gas is present as a gas in the atmosphere before the curable composition and the mold come into contact with each other in the present step. When the present step is carried out under a condensable gas atmosphere, the gas filling the concave portions of the fine pattern is liquefied by a capillary pressure generated from the curable composition, and thus air bubbles are eliminated, so that an excellent filling property is obtained. The condensable gas may be dissolved in the curable composition.

The boiling point of the condensable gas is not limited as long as it is equal to or lower than the atmospheric temperature in the present step, and is preferably −10° C. or higher, +10° C. or higher, and +23° C. or lower.

The vapor pressure of the condensable gas at atmospheric temperature in the present step is not particularly limited as long as it is equal to or lower than the mold pressure. The vapor pressure is preferably in the range of 0.1 MPa to 0.4 MPa.

Specific examples of the condensable gas include chlorofluorocarbon (CFC) such as trichlorofluoromethane, fluorocarbon (FC), hydrochlorofluorocarbon (HCFC), hydrofluorocarbon (HFC) such as 1,1,1,3,3-pentafluoropropane (CHF₂CH₂CF₃, HFC-245fa, PFP), and a hydrofluoroether (HFE) such as pentafluoroethyl methyl ether (CF₃CF₂OCH₃, HFE-245mc).

The condensable gases may be used each alone or in mixture of two or more thereof. In addition, these condensable gases may be mixed with a non-condensable gas such as air, nitrogen, carbon dioxide, helium or argon, and used. The non-condensable gas mixed with the condensable gas is preferably air or helium.

(Step of Irradiating Curable Composition with Light or Electron Beam to Obtain Cured Film)

In the present step, the curable composition is irradiated with a light or electron beam to obtain a cured film. That is, the curable composition filling the fine pattern of the mold is irradiated with a light or electron beam through the mold, and the curable composition filling the fine pattern of the mold is cured as it is, thereby obtaining a cured film having a pattern shape.

The light or electron beam is selected according to a sensitivity wavelength of the curable composition. Specifically, ultraviolet light having a wavelength of 150 nm or more and 400 nm or less, an X-ray, an electron beam, or the like may be appropriately selected, and used. Examples of the light source of a light or electron beam include high-pressure mercury lamps, ultra-high-pressure mercury lamps, low-pressure mercury lamps, Deep-UV lamps, carbon arc lamps, chemical lamps, metal halide lamps, xenon lamps, KrF excimer lasers, ArF excimer lasers, and F2 excimer lasers. The number of light sources may be one or more. The irradiation may be performed on the whole, or only some regions, of the curable composition filling the fine pattern of the mold. The light irradiation may be intermittently performed on all regions on the substrate a plurality of times, or may be continuously performed on all the regions. It is also possible to perform first irradiation on some regions and second irradiation on different regions on the substrate.

The cured film thus obtained preferably has a pattern with a size of 1 nm or more, or 10 nm or more, 10 mm or less, or 100 μm or less.

### (Step of Separating Cured Film and Mold)

In the present step, the cured film and the mold are separated. The cured film having a pattern shape and the mold are separated to obtain a cured film which is in a self-standing state, and has a pattern shape that forms a reverse pattern with respect to the fine pattern formed on the mold.

The method for separating the cured film having a pattern shape and the mold is not particularly limited as long as the cured film and the mold are directed to move away from each other without physically damaging a part of the cured film having a pattern shape. The conditions and the like are not particularly limited. For example, the peeling may be performed by fixing the substrate and moving the mold away from the substrate, or the peeling may be performed by fixing the mold and moving the substrate away from the mold. Alternatively, the peeling may be performed by pulling the substrate and the mold in opposite directions.

When the step of bringing the curable composition and the mold into contact with each other is carried out in a condensable gas atmosphere, the condensable gas vaporizes with a decrease in pressure at the interface where the cured film and the mold are in contact with each other in separation of the cured film and the mold in the present step. This enables reduction of a release force which is a force required to separate the cured film and the mold.

Through the above steps, a cured film may be prepared in which a desired irregular pattern shape derived from irregular shape of the mold is present at a desired location.

### EXAMPLES

The HPLC purity shown in the following synthesis examples of the present specification is a result of measurement by high-performance liquid chromatography (hereinafter, abbreviated as HPLC in the present specification). For the measurement, a HPLC apparatus (LC-2010 A HT) manufactured by Shimadzu Corporation was used. Measurement conditions and the like are as follows.
HPLC column: Inertsil ODS-3 (5 μm, 4.6×250 mm, manufactured by GL Sciences Inc.)
Column temperature: 40° C.
Flow rate: 1.0 mL/min
Solvent: acetonitrile/0.2% phosphoric acid aqueous solution=70/30 (0-5 min.)→70/30 (10-15 min.)

The weight average molecular weight shown in the following synthesis examples of the present specification is a result of measurement by gel permeation chromatography (hereinafter, abbreviated as GPC in the present specification). For the measurement, a GPC apparatus (HLC-8320GPC) manufactured by Tosoh Corporation was used. Measurement conditions and the like are as follows.
GPC column: TSKgelSuperH-RC, TSKgelSuperMultipore HZ-N, TSKgelSuperMultipore HZ-N (manufactured by Tosoh Corporation)
Column temperature: 40° C.
Solvent: tetrahydrofuran (Kanto Chemical Co., Inc., for high-performance liquid chromatography)
Standard sample: polystyrene (manufactured by Shodex)

### <Calculation of Methylolation Ratio>

The methylolation ratio can be calculated from a ¹H-NMR area ratio between hydrogen atoms of methylol groups and arbitrary hydrogen atoms other than those of methylol groups (excluding hydrogen atoms of hydroxy groups). As measurement conditions of 1H-NMR, JNM-ECA500 manufactured by JEOL Ltd. was used, and dimethyl sulfoxide-d₆ was used as a heavy solvent.

### <Synthesis Example 1> Synthesis of Monomer (A) (HM-THPE)

A four-necked flask equipped with a stirring bar and a cooling tube was charged with 30.00 g (98 mmol) of 1,1,1-tris(4-hydroxyphenyl) ethane (Tokyo Chemical Industry Co., Ltd.) and 115.20 g of a 17% sodium hydroxide aqueous solution (Kanto Chemical Co., Inc.), and the mixture was heated to 40° C. while stirring. 48.08 g (592 mmol) of a 37% formaldehyde aqueous solution (Kanto Chemical Co., Inc.) was added thereto by drops at 40° C., and the mixture was stirred at this temperature for 20 hours. To the reaction mixture, 450 g of ethyl acetate (Kanto Chemical Co., Inc.) was added. The mixture was cooled to 10° C. or lower, and 105.01 g of 17% hydrochloric acid was then added thereto by drops. The organic layer was separated, and then washed with 120 g of pure water twice, 120 g of saturated sodium hydrogen carbonate once, and 120 g of pure water twice in this order, and the obtained organic layer was then concentrated at 40° C. under reduced pressure to obtain a monomer (A) with a yield of 72.9%. The monomer had a purity measured by GPC of 75.8%.

### Methylolation Ratio:

$$[ 6.65 \times 3 ( H ) ] / [ 4.7 \times 12 ( H ) ] \times 100 = 35.4 \%$$

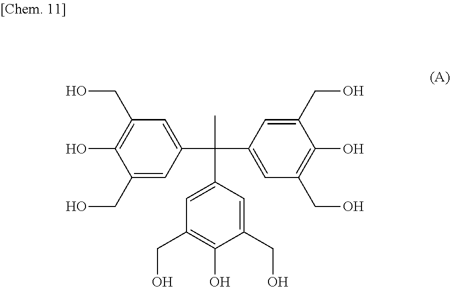 [SMILES: CC(c1cc(CO)c(O)c(CO)c1)(c1cc(CO)c(O)c(CO)c1)c1cc(CO)c(O)c(CO)c1]

### <Synthesis Example 2> Synthesis of Monomer (B) (HM-THPEI)

A four-necked flask equipped with a stirring bar and a cooling tube was charged with 10.00 g (23.6 mmol) of α,α,α′-tris(4-hydroxyphenyl)-1-ethyl-4-isopropylbenzene (Tokyo Chemical Industry Co., Ltd.), 4.74 g of a sodium hydroxide aqueous solution (Kanto Chemical Co., Inc.) and 40.00 g of pure water, and the mixture was heated to 40° C. while stirring. 11.57 g (143 mmol) of a 37% formaldehyde aqueous solution (Kanto Chemical Co., Inc.) was added thereto by drops at 40° C., and the mixture was stirred at this temperature for 27 hours. To the reaction mixture, 160 g of 4-methyl-2-pentanone (Kanto Chemical Co., Inc.) was added. The mixture was cooled to 10° C. or lower, and 25.00 g of 6 N hydrochloric acid (Kanto Chemical Co., Inc.) was then added thereto by drops. The organic layer was separated, and then washed with 40 g of pure water twice, 40 g of saturated sodium hydrogen carbonate once, and 40 g of pure water twice in this order, and the obtained organic layer was then concentrated at 40° C. under reduced pressure to obtain a monomer (B) with a yield of 95.5%. The monomer had a purity measured by GPC of 70.7%.

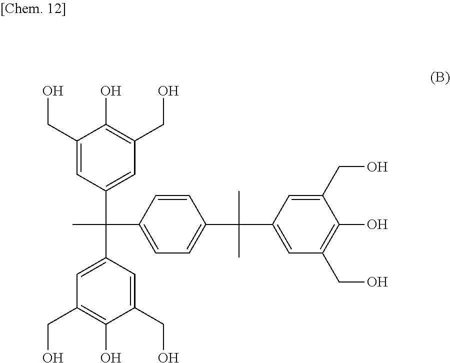 [SMILES: CC(C)(c1ccc(C(C)(c2cc(CO)c(O)c(CO)c2)c2cc(CO)c(O)c(CO)c2)cc1)c1cc(CO)c(O)c(CO)c1]

### <Synthesis Example 3> Synthesis of Monomer (C) (HM-THPE)

A four-necked flask equipped with a stirring bar and a cooling tube was charged with 10.00 g (34.2 mmol) of tris(4-hydroxyphenyl) methane (Tokyo Chemical Industry Co., Ltd.), 6.88 g (171 mmol) of sodium hydroxide (Kanto Chemical Co., Inc.) and 40.00 g of pure water, and the mixture was heated to 40° C. while stirring. 16.8 g (207 mmol) of a 37% formaldehyde aqueous solution (Kanto Chemical Co., Inc.) was added thereto by drops at 40° C., and the mixture was stirred at this temperature for 16 hours. To the reaction mixture, 160 g of 4-methyl-2-pentanone (Kanto Chemical Co., Inc.) was added. The mixture was cooled to 10° C. or lower, and 25 g of 20% hydrochloric acid was then added thereto by drops. The organic layer was separated, and then washed with 40 g of pure water twice, 40 g of saturated sodium hydrogen carbonate once, and 40 g of pure water twice in this order, and the obtained organic layer was then concentrated at 40° C. under reduced pressure to obtain a monomer (C) with a yield of 77.3%. The monomer had a purity measured by GPC of 90.6%.

### Methylolation Ratio:

$$[ 6.34 \times 1 ( H ) ] / [ 1.02 \times 12 ( H ) ] \times 100 = 51.8 \%$$

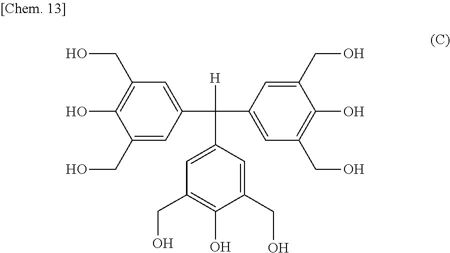 [SMILES: OCc1cc(C(c2cc(CO)c(O)c(CO)c2)c2cc(CO)c(O)c(CO)c2)cc(CO)c1O]

### <Synthesis Example 4> Synthesis of Monomer (D) (TM-DHPPE)

A four-necked flask equipped with a stirring bar and a cooling tube was charged with 10.00 g (34.4 mmol) of 1,1-bis(4-hydroxyphenyl)-1-phenylethane (Tokyo Chemical Industry Co., Ltd.), 4.15 g (103 mmol) of sodium hydroxide (Kanto Chemical Co., Inc.) and 40.00 g of pure water, and the mixture was heated to 40° C. while stirring. 11.32 g (140 mmol) of a 37% formaldehyde aqueous solution (Kanto Chemical Co., Inc.) was added thereto by drops at 40° C., and the mixture was stirred at this temperature for 20 hours. To the reaction mixture, 160 g of 4-methyl-2-pentanone (Kanto Chemical Co., Inc.) was added. The mixture was cooled to 10° C. or lower, and 25 g of 20% hydrochloric acid was then added thereto by drops. The organic layer was separated, and then washed with 40 g of pure water twice, 40 g of saturated sodium hydrogen carbonate once, and 40 g of pure water twice in this order, and the obtained organic layer was then concentrated at 40° C. under reduced pressure to obtain a monomer (D) with a yield of 73.8%. The monomer had a purity measured by GPC of 91.9%.

### Methylolation Ratio:

$$[ 5.06 \times 3 ( H ) ] / [ 3.81 \times 8 ( H ) ] \times 100 = 49.8 \%$$

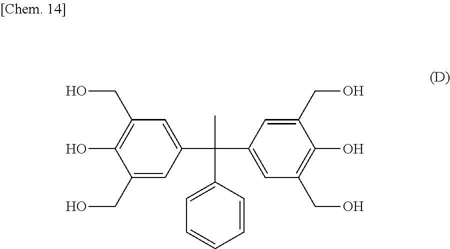 [SMILES: CC(c1ccccc1)(c1cc(CO)c(O)c(CO)c1)c1cc(CO)c(O)c(CO)c1]

### <Synthesis Example 5> Synthesis of Monomer (E) (OM-TEP-TPA)

A four-necked flask equipped with a stirring bar and a cooling tube was charged with 10.00 g (21.1 mmol) of α,α,α′,α′-tetrakis(4-hydroxyphenyl)-p-xylene (Asahi Yukizai Corporation), 5.93 g (148 mmol) of sodium hydroxide (Kanto Chemical Co., Inc.) and 40.00 g of pure water, and the mixture was heated to 40° C. while stirring. 13.77 g (170 mmol) of a 37% formaldehyde aqueous solution (Kanto Chemical Co., Inc.) was added thereto by drops at 40° C., and the mixture was stirred at this temperature for 39.5 hours. To the reaction mixture, 160 g of 4-methyl-2-pentanone (Kanto Chemical Co., Inc.) was added. The mixture was cooled to 10° C. or lower, and 25.00 g of 6N hydrochloric acid (Kanto Chemical Co., Inc.) was then added thereto by drops. The organic layer was separated, and then washed with 40 g of pure water twice, 40 g of saturated sodium hydrogen carbonate once, and 40 g of pure water twice in this order, and the obtained organic layer was then concentrated at 40° C. under reduced pressure. The obtained crystals were dissolved in 30 g of tetrahydrofuran (Kanto Chemical Co., Inc., special grade), and the solution was added by drops to 500 g of toluene (Kanto Chemical Co., Inc.) to produce a precipitate. The obtained crystals were separated by filtration, and the filtrate was washed twice with 10 g of toluene, and dried at 40° C. under reduced pressure to obtain a monomer (E) with a yield of 83.5%. The monomer had a purity measured by GPC of 80.7%.

### Methylolation Ratio:

$$[ 9.50 \times 2 ( H ) ] / [ 2. \times 16 ( H ) ] \times 100 = 59.4 \%$$

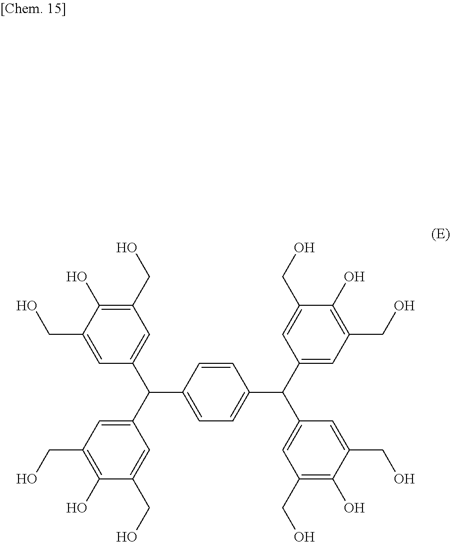 [SMILES: OCc1cc(C(c2ccc(C(c3cc(CO)c(O)c(CO)c3)c3cc(CO)c(O)c(CO)c3)cc2)c2cc(CO)c(O)c(CO)c2)cc(CO)c1O]

### <Synthesis Example 6> Synthesis of Monomer (F) (OM-TEP-DF)

A four-necked flask equipped with a stirring bar and a cooling tube was charged with 10.00 g (25.1 mmol) of 1,1,2,2-tetrakis(4-hydroxyphenyl)ethane (Asahi Yukizai Corporation) and 41.33 g (176 mmol) of a 17% sodium hydroxide aqueous solution (Kanto Chemical Co., Inc.), and the mixture was heated to 40° C. while stirring. 16.40 g (202 mmol) of a 37% formaldehyde aqueous solution (Kanto Chemical Co., Inc.) was added thereto by drops at 40° C., and the mixture was stirred at this temperature for 26 hours. To the reaction mixture, 150 g of ethyl acetate (Kanto Chemical Co., Inc., special grade) was added. The mixture was cooled to 10° C. or lower, and 32.3 g of 17% hydrochloric acid was then added thereto by drops. The organic layer was separated, and then washed with 40 g of pure water twice, 40 g of saturated sodium hydrogen carbonate once, and 40 g of pure water twice in this order, and the obtained organic layer was then concentrated at 40° C. under reduced pressure to obtain a monomer (F) with a yield of 59.6%. The monomer had a purity measured by GPC of 91.7%.

### Methylolation Ratio:

$$[ 5.23 \times 2 ( H ) ] / [ 2. \times 16 ( H ) ] \times 100 = 32.7 \%$$

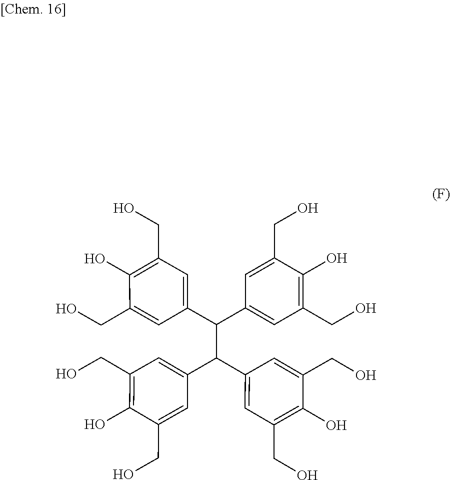 [SMILES: OCc1cc(C(c2cc(CO)c(O)c(CO)c2)C(c2cc(CO)c(O)c(CO)c2)c2cc(CO)c(O)c(CO)c2)cc(CO)c1O]

### <Comparative Synthesis Example 1> Synthesis of Monomer (Cz/BA)

A flask equipped with a stirring bar and a cooling tube was charged with 30.00 g (179.4 mmol) of carbazole (manufactured by Tokyo Chemical Industry Co., Ltd.), 19.04 g (179.42 mmol) of benzaldehyde (manufactured by Tokyo Chemical Industry Co., Ltd.), 0.35 g (3.59 mmol) of methanesulfonic acid (manufactured by Tokyo Chemical Industry Co., Ltd.) and 146.77 g of propylene glycol monomethyl ether acetate. Thereafter, the mixture was heated and refluxed under nitrogen, and stirred for 8 hours. The mixture was cooled to a temperature of 30° C. or lower, and the obtained reaction mixture was then added by drops to 1,800 mL of methanol (Kanto Chemical Co., Inc., special grade) to precipitate a polymer. The obtained precipitate was separated by filtration, and the filtrate was washed with 450 mL of methanol in three parts, and dried under vacuum to obtain a polymer. The polymer had a weight average molecular weight (Mw) measured in terms of standard polystyrene by GPC of 5,795, and was provided in a yield of 50.9%. The polymer has a repeating unit structure represented by the following formula (G). The obtained polymer was diluted to a solid content concentration of 30% with propylene glycol monomethyl ether acetate, a cation-exchange resin and an anion-exchange resin were each added thereto in an amount equal to the solid content amount, and the mixture was stirred for 4 hours. The ion exchange resin was filtered to obtain a polymer solution.

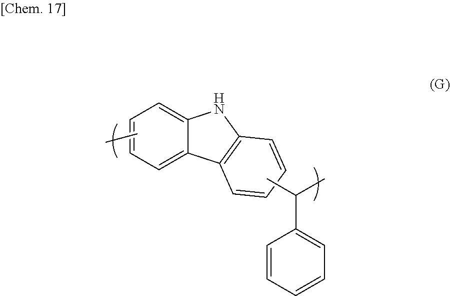

### <Comparative Synthesis Example 2> (Synthesis of Polymer (H)) PBNP-H

A 100 ml-volume two-necked flask was charged under nitrogen with 25.00 g of 2,2′-biphenol (manufactured by Tokyo Chemical Industry Co., Ltd.), 10.5 g of 1-naphthaldehyde (manufactured by Tokyo Chemical Industry Co., Ltd.), 15.5 g of 1-pyrenecarboxaldehyde (manufactured by Aldrich) and 3.87 g of methanesulfonic acid (manufactured by Tokyo Chemical Industry Co., Ltd.). Thereafter, the mixture was heated to 120° C. After about 24 hours, the mixture was allowed to cool to room temperature, precipitated with methanol, and the obtained precipitate was dried. The obtained polymer had a weight average molecular weight Mw measured in terms of standard polystyrene by GPC of 2,000. The obtained polymer was diluted to a solid content concentration of 30% with propylene glycol monomethyl ether acetate, a cation-exchange resin and an anion-exchange resin were each added thereto in an amount equal to the solid content amount, and the mixture was stirred for 4 hours. The ion exchange resin was filtered to obtain a polymer solution.

### <Example 1> 0K20ME1 (HM-THPE)

1.00 g of monomer (A) obtained in Synthesis Example 1 was mixed with 0.10 g of a propylene glycol monomethyl ether acetate solution containing 1% of a surfactant (manufactured by DIC Corporation, product name: MEGAFACE [trade name] R-40, fluorine-based surfactant), 3.60 g of propylene glycol monomethyl ether and 5.30 g of propylene glycol monomethyl ether acetate. Thereafter, the mixture was filtered through a polytetrafluoroethylene microfilter with a pore size of 0.1 μm to prepare a solution of a resist underlayer film-forming composition.

### <Example 2> 0L04ME1 (HM-THPEI)

0.85 g of monomer (B) obtained in Synthesis Example 2 was mixed with 0.09 g of a propylene glycol monomethyl ether acetate solution containing 1% of a surfactant (manufactured by DIC Corporation, product name: MEGAFACE [trade name] R-40, fluorine-based surfactant), 2.75 g of propylene glycol monomethyl ether and 6.32 g of propylene glycol monomethyl ether acetate. Thereafter, the mixture was filtered through a polytetrafluoroethylene microfilter with a pore size of 0.1 μm to prepare a solution of a resist underlayer film-forming composition.

### <Example 3> 1C09ME2 (HM-THPM)

1.08 g of monomer (C) obtained in Synthesis Example 3 was mixed with 0.10 g of a propylene glycol monomethyl ether acetate solution containing 1% of a surfactant (manufactured by DIC Corporation, product name: MEGAFACE [trade name] R-40, fluorine-based surfactant), 2.38 g of propylene glycol monomethyl ether and 5.44 g of propylene glycol monomethyl ether acetate. Thereafter, the mixture was filtered through a polytetrafluoroethylene microfilter with a pore size of 0.1 μm to prepare a solution of a resist underlayer film-forming composition.

### <Example 4> 1C09ME3 (TM-DHPPE)

1.08 g of monomer (D) obtained in Synthesis Example 4 was mixed with 0.12 g of a propylene glycol monomethyl ether acetate solution containing 1% of a surfactant (manufactured by DIC Corporation, product name: MEGAFACE [trade name] R-40, fluorine-based surfactant), 2.38 g of propylene glycol monomethyl ether and 5.43 g of propylene glycol monomethyl ether acetate. Thereafter, the mixture was filtered through a polytetrafluoroethylene microfilter with a pore size of 0.1 μm to prepare a solution of a resist underlayer film-forming composition.

### <Example 5> 0K17ME4 (OM-TEP-TPA)

0.68 g of monomer (E) obtained in Synthesis Example 5 was mixed with 0.07 g of a propylene glycol monomethyl ether acetate solution containing 1% of a surfactant (manufactured by DIC Corporation, product name: MEGAFACE [trade name] R-40, fluorine-based surfactant), 2.20 g of propylene glycol monomethyl ether and 5.06 g of propylene glycol monomethyl ether acetate. Thereafter, the mixture was filtered through a polytetrafluoroethylene microfilter with a pore size of 0.1 μm to prepare a solution of a resist underlayer film-forming composition.

### <Example 6> 1C02ME4 (OM-TEP-DF)

1.49 g of monomer (E) obtained in Synthesis Example 6 was mixed with 0.15 g of a propylene glycol monomethyl ether acetate solution containing 1% of a surfactant (manufactured by DIC Corporation, product name: MEGAFACE [trade name] R-40, fluorine-based surfactant), 0.30 g of a propylene glycol monomethyl ether solution containing 1% of pyridinium p-toluenesulfonate, 2.27 g of propylene glycol monomethyl ether and 5.80 g of propylene glycol monomethyl ether acetate. Thereafter, the mixture was filtered through a polytetrafluoroethylene microfilter with a pore size of 0.1 μm to prepare a solution of a resist underlayer film-forming composition.

### <Example 7> 1C09ME4 (TM-BIP-BZ)

1.20 g of TM-BIP-BZ (manufactured by Asahi Yukizai Corporation) was mixed with 0.12 g of a propylene glycol monomethyl ether acetate solution containing 1% of a surfactant (manufactured by DIC Corporation, product name: MEGAFACE [trade name] R-40, fluorine-based surfactant), 2.64 g of propylene glycol monomethyl ether and 6.04 g of propylene glycol monomethyl ether acetate. Thereafter, the mixture was filtered through a polytetrafluoroethylene microfilter with a pore size of 0.1 μm to prepare a solution of a resist underlayer film-forming composition.

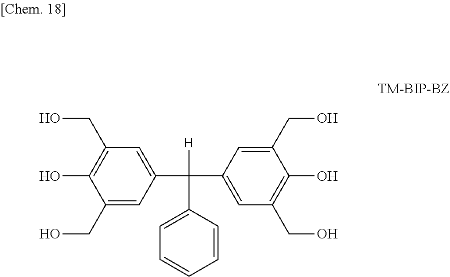 [SMILES: OCc1cc(C(c2ccccc2)c2cc(CO)c(O)c(CO)c2)cc(CO)c1O]

### <Example 8> 0K20ME2 (HMOM-TPPA)

1.00 g of TMOM-TPPA (manufactured by Honshu Chemical Industry Co., Ltd.) was mixed with 0.10 g of a propylene glycol monomethyl ether acetate solution containing 1% of a surfactant (manufactured by DIC Corporation, product name: MEGAFACE [trade name] R-40, fluorine-based surfactant), 1.00 g of a propylene glycol monomethyl ether solution containing 1% of pyridinium p-toluenesulfonate, 1.71 g of propylene glycol monomethyl ether and 6.20 g of propylene glycol monomethyl ether acetate. Thereafter, the mixture was filtered through a polytetrafluoroethylene microfilter with a pore size of 0.1 μm to prepare a solution of a resist underlayer film-forming composition.

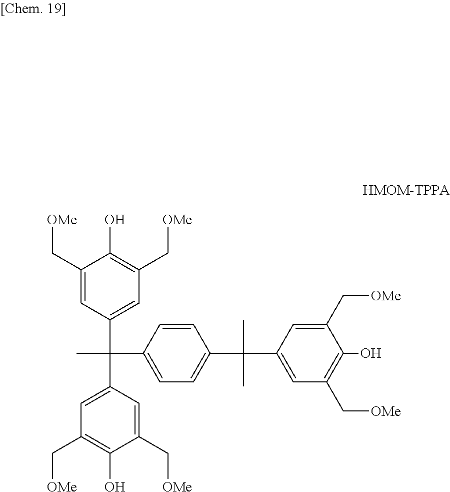 [SMILES: COCc1cc(C(C)(C)c2ccc(C(C)(c3cc(COC)c(O)c(COC)c3)c3cc(COC)c(O)c(COC)c3)cc2)cc(COC)c1O]

### <Example 9> 1B24HH1 (TM-BIP-ANT)

1.99 g of TM-BIP-ANT (manufactured by Asahi Yukizai Corporation) was mixed with 0.19 g of a propylene glycol monomethyl ether acetate solution containing 1% of a surfactant (manufactured by DIC Corporation, product name: MEGAFACE [trade name] R-40, fluorine-based surfactant), 5.4 g of propylene glycol monomethyl ether and 12.4 g of propylene glycol monomethyl ether acetate. Thereafter, the mixture was filtered through a polytetrafluoroethylene microfilter with a pore size of 0.1 μm to prepare a solution of a resist underlayer film-forming composition.

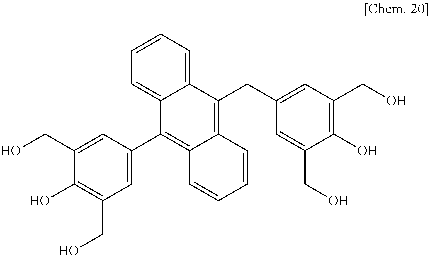 [SMILES: OCc1cc(Cc2c3ccccc3c(-c3cc(CO)c(O)c(CO)c3)c3ccccc23)cc(CO)c1O]

### <Example 10> 1B24HH1 (TPA-8MX)

1.99 g of TPA-8MX (manufactured by Asahi Yukizai Corporation) was mixed with 0.19 g of a propylene glycol monomethyl ether acetate solution containing 1% of a surfactant (manufactured by DIC Corporation, product name: MEGAFACE [trade name] R-40, fluorine-based surfactant), 5.4 g of propylene glycol monomethyl ether, 12.4 g of propylene glycol monomethyl ether acetate and 11.5 g of cyclohexanone. Thereafter, the mixture was filtered through a polytetrafluoroethylene microfilter with a pore size of 0.1 μm to prepare a solution of a resist underlayer film-forming composition.

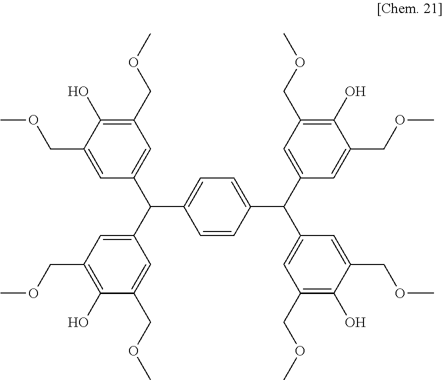

### <Comparative Example 1> Cz/BA, TMOM-BP (9%)

43.91 g of the resin obtained in Comparative Synthesis Example 1 was mixed with 1.23 g of a propylene glycol monomethyl ether acetate solution containing 1% of a surfactant (manufactured by DIC Corporation, product name: MEGAFACE [trade name] R-40, fluorine-based surfactant), 1.23 g of TMOM-BP (manufactured by Honshu Chemical Industry Co., Ltd.), 12.25 g of a propylene glycol monomethyl ether solution containing 1% of pyridinium p-toluenesulfonate, 28.82 g of propylene glycol monomethyl ether and 62.68 g of propylene glycol monomethyl ether acetate. Thereafter, the mixture was filtered through a polytetrafluoroethylene microfilter with a pore size of 0.1 μm to prepare a solution of a resist underlayer film-forming composition.

### <Comparative Example 2> Cz/BA, HM-THPE (9%) 1C18ME5

3.24 g of the resin obtained in Comparative Synthesis Example 1 was mixed with 0.09 g of a propylene glycol monomethyl ether acetate solution containing 1% of a surfactant (manufactured by DIC Corporation, product name: MEGAFACE [trade name] R-40, fluorine-based surfactant), 0.09 g of monomer (A) obtained in Synthesis Example 1, 0.18 g of a propylene glycol monomethyl ether solution containing 5% of pyridinium p-toluenesulfonate, 2.53 g of propylene glycol monomethyl ether and 3.88 g of propylene glycol monomethyl ether acetate. Thereafter, the mixture was filtered through a polytetrafluoroethylene microfilter with a pore size of 0.1 μm to prepare a solution of a resist underlayer film-forming composition.

### <Comparative Example 3> Cz/BA, HM-THPE (33%) 1C18ME6

2.37 g of the resin obtained in Comparative Synthesis Example 1 was mixed with 0.07 g of a propylene glycol monomethyl ether acetate solution containing 1% of a surfactant (manufactured by DIC Corporation, product name: MEGAFACE [trade name] R-40, fluorine-based surfactant), 0.33 g of monomer (A) obtained in Synthesis Example 1, 0.13 g of a propylene glycol monomethyl ether solution containing 1% of pyridinium p-toluenesulfonate, 2.57 g of propylene glycol monomethyl ether and 4.53 g of propylene glycol monomethyl ether acetate. Thereafter, the mixture was filtered through a polytetrafluoroethylene microfilter with a pore size of 0.1 μm to prepare a solution of a resist underlayer film-forming composition.

### <Comparative Example 4> Cz/BA, HM-THPE (38%) 1C24ME1

2.22 g of the resin obtained in Comparative Synthesis Example 1 was mixed with 0.06 g of a propylene glycol monomethyl ether acetate solution containing 1% of a surfactant (manufactured by DIC Corporation, product name: MEGAFACE [trade name] R-40, fluorine-based surfactant), 0.37 g of monomer (A) obtained in Synthesis Example 1, 0.13 g of a propylene glycol monomethyl ether solution containing 1% of pyridinium p-toluenesulfonate, 2.58 g of propylene glycol monomethyl ether and 4.64 g of propylene glycol monomethyl ether acetate. Thereafter, the mixture was filtered through a polytetrafluoroethylene microfilter with a pore size of 0.1 μm to prepare a solution of a resist underlayer film-forming composition.

### Comparative Example 5

0.10 g of propylene glycol monomethyl ether acetate containing a 1% by mass surfactant (manufactured by DIC Corporation, MEGAFACE R-40), 3.68 g of propylene glycol monomethyl ether acetate and 2.68 g of propylene glycol monomethyl ether were added to and dissolved in 3.02 g of the resin solution (solid content: 29.9% by mass) obtained in Comparative Synthesis Example 2, and the solution was filtered through a polytetrafluoroethylene microfilter with a pore size of 0.1 μm to prepare a solution of a resist underlayer film-forming composition.

### <Film Formation Test in Atmospheric Air>

### (Elution Test in Photoresist Solvent)

The resist underlayer film-forming composition solution prepared in each of Examples 1 to 8 and Comparative Examples 1 to 4 was applied onto a silicon wafer using a spin coater. A resist underlayer film (thickness: 60 nm) was formed by baking the applied film on a hot plate at 300° C. for 90 seconds. The resist underlayer films were immersed in a PGME/PGMEA mixed solvent (mixing ratio on a mass basis: 70/30) which is a solvent used for a photoresist solution. When the resist underlayer film was insoluble in the solvent, “∘” was assigned. Table 1 shows the results.

TABLE 1

| | Solvent resistance |
|---|---|
| Example 1 | ◯ |
| Example 2 | ◯ |
| Example 3 | ◯ |
| Example 4 | ◯ |
| Example 5 | ◯ |
| Example 6 | ◯ |
| Example 7 | ◯ |
| Example 8 | ◯ |
| Comparative | ◯ |
| Example 1 | |
| Comparative | ◯ |
| Example 2 | |
| Comparative | ◯ |
| Example 3 | |
| Comparative | ◯ |
| Example 4 | |

### (Measurement of Optical Constant)

The resist underlayer film-forming composition solution prepared in each of Examples 1 to 8 and Comparative Examples 1 to 4 was applied onto a silicon wafer using a spin coater. A resist underlayer film (thickness: 50 nm) was formed by baking the applied film on a hot plate at 40° C. for 90 seconds. For the resist underlayer film, the refractive index (n value) and the optical absorption coefficient (k value, also referred to as an attenuation coefficient) at a wavelength of 193 nm were measured using a spectroscopic ellipsometer. Table 2 shows the results.

TABLE 2

| | n/k 193 nm |
|---|---|
| Example 1 | 1.43/0.50 |
| Example 2 | 1.45/0.55 |
| Example 3 | 1.41/0.47 |
| Example 4 | 1.50/0.60 |
| Example 5 | 1.45/0.50 |
| Example 6 | 1.43/0.46 |
| Example 7 | 1.48/0.54 |
| Example 8 | 1.45/0.52 |
| Comparative | 1.48/0.54 |
| Example 1 | |
| Comparative | 1.48/0.55 |
| Example 2 | |
| Comparative | 1.48/0.55 |
| Example 3 | |
| Comparative | 1.44/0.54 |
| Example 4 | |

With the resist underlayer film-forming composition prepared in each of Examples 1 to 8 and Comparative Examples 1 to 4, a resist underlayer film was formed on a silicon wafer by the same method as described above. Using RIE-10NR (manufactured by SAMCO Inc.), the dry etching rate of the resist underlayer film was measured under the conditions of using O₂/N₂ as an etching gas. The dry etching rate of each of the resist underlayer films when the dry etching rate in Comparative Examples 1 is assumed to be 1.00 was calculated. Table 3 shows the results as “relative dry etching rates”.

TABLE 3

| | Etching rate |
|---|---|
| Example 1 | 1.56 |
| Example 2 | 1.31 |
| Example 3 | 1.62 |
| Example 4 | 1.19 |
| Example 5 | 1.38 |
| Example 6 | 1.60 |
| Example 7 | 1.38 |
| Example 8 | 1.59 |
| Comparative | 1.00 |
| Example 1 | |
| Comparative | 1.17 |
| Example 2 | |
| Comparative | 1.18 |
| Example 3 | |
| Comparative | 1.23 |
| Example 4 | |

As seen above, the etching resistance of the resist underlayer film can be freely controlled by changing the type of the monomer.

### (Measurement of Amount of Sublimates of Resist Underlayer Film)

The measurement of was performed using a sublimate amount measuring apparatus disclosed in WO 2007/111147 A. The resist underlayer film-forming composition prepared in each of Examples 1 to 3, 5, 6 and 8 and Comparative Examples 1 to 4 was applied onto a silicon wafer, and the amount of sublimates when the thickness reached 50 nm after baking at 400° C. for 90 seconds was measured. Table 4 shows the results. The value shown in the table is (amount of sublimates in each Example or Comparative Example)/(amount of sublimates in Comparative Example 1).

TABLE 4

| | Amount of sublimates |
|---|---|
| Example 1 | 0.71 |
| Example 2 | 0.41 |
| Example 3 | 0.65 |
| Example 5 | 0.06 |
| Example 6 | 0.47 |
| Example 8 | 0.82 |
| Comparative | 1.00 |
| Example 1 | |
| Comparative | 2.08 |
| Example 2 | |
| Comparative | 0.98 |
| Example 3 | |
| Comparative | 1.02 |
| Example 4 | |

### (Hardness Test)

The resist underlayer film-forming composition prepared in each of Examples 1 to 8 and Comparative Examples 1 to 4 was applied onto a silicon wafer, and then baked at 400° C. for 90 seconds to form a 200 nm resist underlayer film. The elastic modulus and the hardness of the cured resist film were evaluated by TI-980 triboidentor manufactured by Bruker. Table 5 shows the results.

TABLE 5

| | Hardness (GPa) |
|---|---|
| Example 1 | 0.81 |
| Example 2 | 0.72 |
| Example 3 | 0.87 |
| Example 4 | 0.69 |
| Example 5 | 0.79 |
| Example 6 | 0.89 |
| Example 7 | 0.73 |
| Example 8 | 0.74 |
| Comparative | 0.54 |
| Example 1 | |
| Comparative | 0.58 |
| Example 2 | |
| Comparative | 0.66 |
| Example 3 | |
| Comparative | 0.55 |
| Example 4 | |

As seen above, the effect of increasing the hardness is low when a monomer is used as a cross-linking agent, but the hardness of the resist underlayer film can be significantly increased by using a material having a cross-linked structure.

### <Film Formation Test in Nitrogen Atmosphere>

### (Measurement of Film Shrinkage Ratio)

The resist underlayer film-forming composition prepared in each of Examples 1, 5, 9 and 10 and Comparative Examples 1 to 5 was applied onto a silicon wafer using a spin coater. Thereafter, a resist underlayer film (thickness: about 0.25 μm) was formed by baking the applied film on a hot plate in atmospheric air at 350° C. for 1 minute, and a thickness A was measured. The substrate was further baked at 450° C. for 5 minutes, at 550° C. for 5 minutes or at 600° C. for 5 minutes in a nitrogen atmosphere, and a thickness B was measured. A value determined from (1−thickness B/thickness A)×100 was taken as a film shrinkage ratio.

The results of comparison between the films baked under the same baking conditions showed that the film shrinkage ratio of the underlayer film obtained from the resist underlayer film-forming composition prepared in each of Examples 1, 5, 9 and 10 was smaller than the film shrinkage ratio of the underlayer film obtained from the resist underlayer film-forming composition prepared in Comparative Example 1 or Comparative Example 5. This leads to an advantage that the amount of sublimates is small, so that contamination of the apparatus is reduced. Also, a smaller shrinkage ratio is more advantageous for in-plane uniformity of the film.

TABLE 6

| | | Shrinkage |
|---|---|---|
| | Baking conditions | ratio |
| Example 1 | 350° C./60 seconds + 450° C./5 minutes N₂ | 1% |
| Example 5 | 350° C./60 seconds + 450° C./5 minutes N₂ | 6% |
| Example 9 | 350° C./60 seconds + 450° C./5 minutes N₂ | 0% |
| Example 10 | 350° C./60 seconds + 450° C./5 minutes N₂ | 1% |
| Comparative | 350° C./60 seconds + 450° C./5 minutes N₂ | 9% |
| Example 1 | | |
| Comparative | 350° C./60 seconds + 450° C./5 minutes N₂ | 9% |
| Example 5 | | |

TABLE 7

| | | Shrinkage |
|---|---|---|
| | Baking conditions | ratio |
| Example 1 | 350° C./60 seconds + 500° C./5 minutes | 21% |
| | (HP) N₂ | |
| Example 5 | 350° C./60 seconds + 500° C./5 minutes | 12% |
| | (HP) N₂ | |
| Example 9 | 350° C./60 seconds + 500° C./5 minutes | 16% |
| | (HP) N₂ | |
| Example 10 | 350° C./60 seconds + 500° C./5 minutes | 19% |
| | (HP) N₂ | |
| Comparative | 350° C./60 seconds + 500° C./5 minutes | 25% |
| Example 5 | (HP) N₂ | |

TABLE 8

| | | Shrinkage |
|---|---|---|
| | Baking conditions | ratio |
| Example 1 | 350° C./60 seconds + 600° C./5 minutes | 21% |
| | (HP) N₂ | |
| Example 5 | 350° C./60 seconds + 600° C./5 minutes | 18% |
| | (HP) N₂ | |
| Example 9 | 350° C./60 seconds + 600° C./5 minutes | 13% |
| | (HP) N₂ | |
| Example 10 | 350° C./60 seconds + 600° C./5 minutes | 24% |
| | (HP) N₂ | |
| Comparative | 350° C./60 seconds + 600° C./5 minutes | 47% |
| Example 1 | (HP) N₂ | |
| Comparative | 350° C./60 seconds + 600° C./5 minutes | 33% |
| Example 5 | (HP) N₂ | |

### (Hardness Test)

With the resist underlayer film-forming composition prepared in each of Examples 1, 5, 9, 10 and Comparative Examples 1 and 5, a resist underlayer film was formed on a silicon wafer by the same method as described above. Using a nanoindenter manufactured by TOYO Corporation, a nanoindentation test was conducted to measure the hardness of the resist underlayer film. Comparison between films baked under the same baking conditions showed that Examples 1, 5, 9 and 10 were advantageous for processing by baking, because they exhibited a higher hardness than did Comparative Examples 1 and 5 even in the case of baking in a nitrogen atmosphere.

TABLE 9

| | | Hardness |
|---|---|---|
| | Baking conditions | [GPa] |
| Example 1 | 350° C./60 seconds + 450° C./5 minutes N₂ | 1.33 |
| Example 5 | 350° C./60 seconds + 450° C./5 minutes N₂ | 0.90 |
| Example 9 | 350° C./60 seconds + 450° C./5 minutes N₂ | 0.91 |
| Example 10 | 350° C./60 seconds + 450° C./5 minutes N₂ | 1.06 |
| Comparative | 350° C./60 seconds + 450° C./5 minutes N₂ | 0.57 |
| Example 1 | | |
| Comparative | 350° C./60 seconds + 450° C./5 minutes N₂ | 0.42 |
| Example 5 | | |

TABLE 10

| | | Hardness |
|---|---|---|
| | Baking conditions | [GPa] |
| Example 1 | 350° C./60 seconds + 500° C./5 minutes | 1.17 |
| | (HP) N₂ | |
| Example 5 | 350° C./60 seconds + 500° C./5 minutes | 1.26 |
| | (HP) N₂ | |
| Example 9 | 350° C./60 seconds + 500° C./5 minutes | 1.51 |
| | (HP) N₂ | |
| Example 10 | 350° C./60 seconds + 500° C./5 minutes | 1.55 |
| | (HP) N₂ | |
| Comparative | 350° C./60 seconds + 500° C./5 minutes | 1.48 |
| Example 1 | (HP) N₂ | |
| Comparative | 350° C./60 seconds + 500° C./5 minutes | 0.58 |
| Example 5 | (HP) N₂ | |

TABLE 11

| | | Hardness |
|---|---|---|
| | Baking conditions | [GPa] |
| Example 1 | 350° C./60 seconds + 600° C./5 minutes | 2.23 |
| | (HP) N₂ | |
| Example 5 | 350° C./60 seconds + 600° C./5 minutes | 1.96 |
| | (HP) N₂ | |
| Example 9 | 350° C./60 seconds + 600° C./5 minutes | 2.18 |
| | (HP) N₂ | |
| Example 10 | 350° C./60 seconds + 600° C./5 minutes | 2.09 |
| | (HP) N₂ | |
| Comparative | 350° C./60 seconds + 600° C./5 minutes | 1.48 |
| Example 1 | (HP) N₂ | |
| Comparative | 350° C./60 seconds + 600° C./5 minutes | 1.45 |
| Example 5 | (HP) N₂ | |

### (Measurement of Dry Etching Rate)

The resist underlayer film-forming composition prepared in each of Examples 1, 5, 9 and 10 and Comparative Examples 1 to 5 was applied onto a silicon wafer using a spin coater. Thereafter, a resist underlayer film (thickness: about 0.2 μm) was formed by baking the applied film on a hot plate at 350° C. for 1 minute, then at 450° C. for 5 minutes, 550° C. for 5 minutes or 600° C. for 5 minutes in a nitrogen atmosphere. Using RIE System manufactured by SAMCO Inc., the dry etching rate of the resist underlayer film was measured under the conditions of using CF₄ as a dry etching gas.

The dry etching rate when the dry etching rate (E.R.) of the film baked at 400° C. for 90 seconds in Comparative Examples 1 is assumed to be 1.00 was calculated. Tables below show the results as “relative dry etching rates”. It is shown that The resist underlayer films formed in Examples 1, 5 and 10, in which the baking was performed at 500° C. for 5 minutes, and the resist underlayer film formed in Example 5, in which the baking was performed at 600° C. for 5 minutes, have high etching resistance and are advantageous for processing by etching, because they exhibit low E. R. while possessing such properties as low film shrinkage ratio and high hardness.

TABLE 12

| | Baking conditions | E.R. |
|---|---|---|
| Example 1 | 350° C./60 seconds + 450° C./5 minutes N₂ | 1.27 |
| Example 5 | 350° C./60 seconds + 450° C./5 minutes N₂ | 1.18 |
| Example 9 | 350° C./60 seconds + 450° C./5 minutes N₂ | 1.11 |
| Example 10 | 350° C./60 seconds + 450° C./5 minutes N₂ | 1.34 |
| Comparative | 350° C./60 seconds + 450° C./5 minutes N₂ | 0.94 |
| Example 1 | | |
| Comparative | 350° C./60 seconds + 450° C./5 minutes N₂ | 0.90 |
| Example 5 | | |

TABLE 13

| | Baking conditions | E.R. |
|---|---|---|
| Example 1 | 350° C./60 seconds + 500° C./5 minutes (HP) N₂ | 1.08 |
| Example 5 | 350° C./60 seconds + 500° C./5 minutes (HP) N₂ | 0.97 |
| Example 9 | 350° C./60 seconds + 500° C./5 minutes (HP) N₂ | 1.19 |
| Example 10 | 350° C./60 seconds + 500° C./5 minutes (HP) N₂ | 0.96 |
| Comparative | 350° C./60 seconds + 500° C./5 minutes (HP) N₂ | 1.11 |
| Example 1 | | |
| Comparative | 350° C./60 seconds + 500° C./5 minutes (HP) N₂ | 0.98 |
| Example 5 | | |

TABLE 14

| | Baking conditions | E.R. |
|---|---|---|
| Example 1 | 350° C./60 seconds + 600° C./5 minutes (HP) N₂ | 1.15 |
| Example 5 | 350° C./60 seconds + 600° C./5 minutes (HP) N₂ | 0.87 |
| Example 9 | 350° C./60 seconds + 600° C./5 minutes (HP) N₂ | 1.15 |
| Example 10 | 350° C./60 seconds + 600° C./5 minutes (HP) N₂ | 1.20 |
| Comparative | 350° C./60 seconds + 600° C./5 minutes (HP) N₂ | 1.22 |
| Example 1 | | |
| Comparative | 350° C./60 seconds + 600° C./5 minutes (HP) N₂ | 0.94 |
| Example 5 | | |

### INDUSTRIAL APPLICABILITY

According to the present invention, there is provided a novel resist underlayer film-forming composition which meets the requirements of reduction of the amount of sublimates that would contaminate an apparatus, and enhancement of etching resistance in processing of a substrate and bending resistance of the resulting resist underlayer film, hardness in particular, while maintaining the other desirable properties.

1. A resist underlayer film-forming composition comprising a compound P having a partial structure comprising a benzene ring carrying thereon a phenolic hydroxy group and at least one hydroxymethyl or methoxymethyl group in an ortho position relative to the phenolic hydroxy group,
wherein the resist underlayer film-forming composition contains the compound P in a content of 80% by mass or more based on a total solid content in the composition.

2. The resist underlayer film-forming composition according to claim 1, wherein the compound P is a compound represented by the following Formula (1): 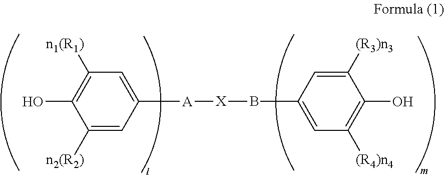
wherein R¹, R², R³ and R⁴ each independently represent a hydrogen atom, a hydroxymethyl group, or a methoxymethyl group,
A and B each independently represent an alkylene group having 1 or 2 carbon atoms and optionally substituted with a benzene ring or an alkyl group having 1 to 10 carbon atoms, or a single bond,
X represents an alkylene group having 1 or 2 carbon atoms and optionally substituted with a benzene ring or an alkyl group having 1 to 10 carbon atoms, an arylene group, or a single bond,
l and m each independently represent 1 or 2,
n1 to n4 are each independently 0 or 1, and satisfy
$$( ( n 1 + n 2 ) l + ( n 3 + n 4 ) m ) / ( 2 l + 2 m ) \geq 0.3 ,$$
with the proviso that not all of A, B and X is a single bond.

3. The resist underlayer film-forming composition according to claim 1, wherein the resist underlayer film-forming composition contains the compound P in a content of 90% by mass or more based on a total solid content in the composition.

4. The resist underlayer film-forming composition according to claim 2, wherein in Formula (1), each of R¹, R², R³ and R⁴ is a hydroxymethyl group.

5. The resist underlayer film-forming composition according to claim 1, further comprising an acid and/or an acid generator.

6. The resist underlayer film-forming composition according to claim 1, further comprising a surfactant.

7. The resist underlayer film-forming composition according to claim 1, wherein the solvent includes a solvent having a boiling point of 160° C. or higher.

8. A resist underlayer film which is a baked product of a coating film of the composition according to claim 1.

9. A method for producing a semiconductor device, comprising:
forming a resist underlayer film on a semiconductor substrate using the composition according to claim 1;
forming a resist film on the formed resist underlayer film;
forming a resist pattern by irradiating the formed resist film with a light or electron beam and developing the irradiated film;
etching the resist underlayer film via the formed resist pattern to make a patterned resist underlayer film; and
processing the semiconductor substrate via the patterned resist underlayer film.

10. A method for producing a semiconductor device, comprising:
forming a resist underlayer film on a semiconductor substrate using the composition according to claim 1;
forming a hard mask on the formed resist underlayer film;
forming a resist film on the formed hard mask;
forming a resist pattern by irradiating the formed resist film with a light or electron beam and developing the irradiated film;
etching the hard mask via the formed resist pattern to make a patterned hard mask;
etching the resist underlayer film via the patterned hard mask to make a patterned resist underlayer film; and
processing the semiconductor substrate via the patterned resist underlayer film.
